(19) United States
(12) Patent Application Publication
(10) Pub. No.: US 2025/0046739 A1
(43) Pub. Date: Feb. 6, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Chin-Hao HSU, Taichung City (TW); Anhao CHENG, Taichung City (TW); Yen-Liang LIN, Tainan City (TW); Ru-Shang HSIAO, Jhubei City (TW)

(21) Appl. No.: 18/500,878

(22) Filed: Nov. 2, 2023

Related U.S. Application Data
(60) Provisional application No. 63/517,274, filed on Aug. 2, 2023.

(51) Int. Cl. H01L 23/00; H01L 21/768; H01L 23/522

(52) U.S. Cl. CPC H01L 24/08; H01L 21/768; H01L 23/5226; H01L 24/80; H01L 2224/08145; H01L 2224/80379

(57) ABSTRACT

A metal layer of a semiconductor device may be included in an extreme low dielectric constant (ELK) dielectric layer in an interconnect structure of the semiconductor device. The metal layer may be coupled with a bonding via that extends through a silicon carbide (SiC) layer in a bonding region of the semiconductor device. The ELK dielectric layer and/or the silicon carbide layer reduces stress migration in the semiconductor relative to the use of other dielectric materials such as silicon nitride and/or silicon glass. The ELK dielectric layer and/or the silicon carbide layer also reduces resistance-capacitance (RC) delay in the interconnect structure relative to the use of other dielectric materials. The ELK dielectric layer and/or the silicon carbide layer provides improved adhesion with the metal material(s) (e.g., copper and/or another metal material) of the metal layer and/or of the bonding via coupled with the metal layer.

### CROSS-REFERENCE TO RELATED APPLICATION

This patent application claims priority to U.S. Provisional Application No. 63/517,274, filed on Aug. 2, 2023, and entitled “SEMICONDUCTOR DEVICE AND METHODS OF FORMATION.” The disclosure of the prior application is considered part of and is incorporated by reference into this patent application.

### BACKGROUND

Bonding in the semiconductor industry is a technique that may be used to form stacked semiconductor devices and three-dimensional integrated circuits. Some examples of bonding include wafer-to-wafer bonding, die-to-wafer bonding, and die-to-die bonding, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2G are diagrams of examples of a semiconductor device described herein.

FIGS. 3A-3N are diagrams of an example implementation of forming a semiconductor die described herein.

FIGS. 4A and 4B are diagrams of an example implementation of forming a semiconductor device described herein.

FIGS. 5A and 5B are diagrams of an example implementation of the semiconductor device described herein.

FIG. 6 is a diagram of example components of a device described herein.

FIG. 7 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Bonding pads and bonding vias are widely used for bonding semiconductor wafers. Copper (Cu) is a metal that is usually used for bonding pads and bonding vias. Silicon nitride (SiₓN_{y}) is a dielectric material that may be used in one or more dielectric layers around the bonding pads and/or bonding vias. While silicon nitride may provide etch selectivity as an etch stop layer, silicon nitride may have poor adhesion with metals such as copper, which may cause stress migration in a semiconductor device and may result in degraded performance and/or semiconductor device failure. Stress migration may refer to stresses (e.g., thermal stresses, vibration stresses) that are transferred from the bonding pads and/or bonding vias to the surrounding dielectric layers, and that result in void formation, increased electrical resistance in the bonding pads and/or bonding vias, and/or semiconductor device failure. The thermal stresses may occur due to mismatches in thermal expansion and contraction that occur between the bonding pads and/or bonding vias and the surrounding dielectric layers. The temperature of a semiconductor device may be elevated during deposition of the bonding pads and/or bonding vias, and the temperature may decrease after deposition as the bonding pads and/or bonding vias cool back down to room temperature. The heating and cooling of the semiconductor device may result in the mismatches of thermal expansion and contraction, which may cause the bonding pads and/or bonding vias to exert a tensile stress on the surrounding dielectric layers.

In some implementations described herein, a semiconductor device includes a device layer that includes one or more devices, and an interconnect structure above the device layer, and a bonding region above the interconnect structure that includes a plurality of metallization layers in a plurality of dielectric layers. The interconnect structure includes a metal layer that is coupled with an bonding via in the bonding region, and the bonding via is coupled with a bonding pad in the bonding region. The bonding pad of the semiconductor device may be bonded with a bonding pad of another semiconductor device.

The metal layer is included in an extreme low dielectric constant (ELK) dielectric layer of the interconnect structure, and/or the bonding via extends through a silicon carbide (SiC) layer in the bonding region. The ELK dielectric layer and/or the silicon carbide layer reduces stress migration in the semiconductor relative to the use of other dielectric materials such as silicon nitride and/or silicon glass. The ELK dielectric layer and/or the silicon carbide layer also reduces resistance-capacitance (RC) delay in the interconnect structure relative to the use of other dielectric materials. The ELK dielectric layer and/or the silicon carbide layer provides improved adhesion with the metal material(s) (e.g., copper and/or another metal material) of the metal layer and/or of the bonding via coupled with the metal layer. This may reduce the likelihood of stress migration in the semiconductor device, thereby reducing the likelihood of void formation in the semiconductor device. The reduced likelihood of void formation may reduce electrical resistance in the interconnect structure and/or in the bonding region, which may improve the performance of the semiconductor device and/or may increase semiconductor processing yield of semiconductor devices formed on a semiconductor wafer, among other examples.

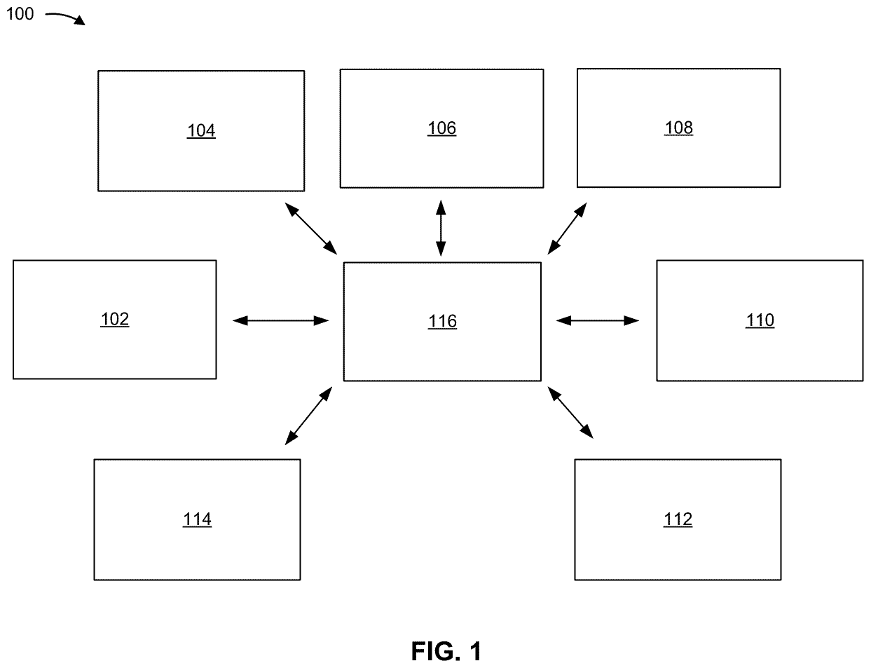

FIG. 1 is a diagram of an example environment 100 in which systems and/or methods described herein may be implemented. As shown in FIG. 1, the example environment 100 may include a plurality of semiconductor processing tools 102-114 and a wafer/die transport tool 116. The plurality of semiconductor processing tools 102-112 may include a deposition tool 102, an exposure tool 104, a developer tool 106, an etch tool 108, a planarization tool 110, a plating tool 112, a bonding tool 114, and/or another type of semiconductor processing tool. The tools included in example environment 100 may be included in a semiconductor clean room, a semiconductor foundry, a semiconductor processing facility, and/or manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a high-density plasma CVD (HDP-CVD) tool, a sub-atmospheric CVD (SACVD) tool, a low-pressure CVD (LPCVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the deposition tool 102 includes an epitaxial tool that is configured to form layers and/or regions of a device by epitaxial growth. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The bonding tool 114 is a semiconductor processing tool that is capable of bonding two or more work pieces (e.g., two or more semiconductor substrates, two or more semiconductor devices, two or more semiconductor dies) together. For example, the bonding tool 114 is a type of bonding tool that is configured to bond semiconductor dies and/or wafers together directly through metal-to-metal bonds and/or dielectric-to-dielectric bonds. As another example, the bonding tool 114 may include a eutectic bonding tool that is capable of forming a eutectic bond between two or more wafers together. In these examples, the bonding tool 114 may heat the two or more wafers to form a eutectic system between the materials of the two or more wafers.

Wafer/die transport tool 116 includes a mobile robot, a robot arm, a tram or rail car, an overhead hoist transport (OHT) system, an automated materially handling system (AMHS), and/or another type of device that is configured to transport substrates and/or semiconductor devices between semiconductor processing tools 102-114, that is configured to transport substrates and/or semiconductor devices between processing chambers of the same semiconductor processing tool, and/or that is configured to transport substrates and/or semiconductor devices to and from other locations such as a wafer rack, a storage room, and/or the like. In some implementations, wafer/die transport tool 116 may be a programmed device that is configured to travel a particular path and/or may operate semi-autonomously or autonomously. In some implementations, the example environment 100 includes a plurality of wafer/die transport tools 116.

For example, the wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations). In these implementations, the wafer/die transport tool 116 is configured to transport substrates and/or semiconductor devices between the processing chambers of the deposition tool 102 without breaking or removing a vacuum (or an at least partial vacuum) between the processing chambers and/or between processing operations in the deposition tool 102.

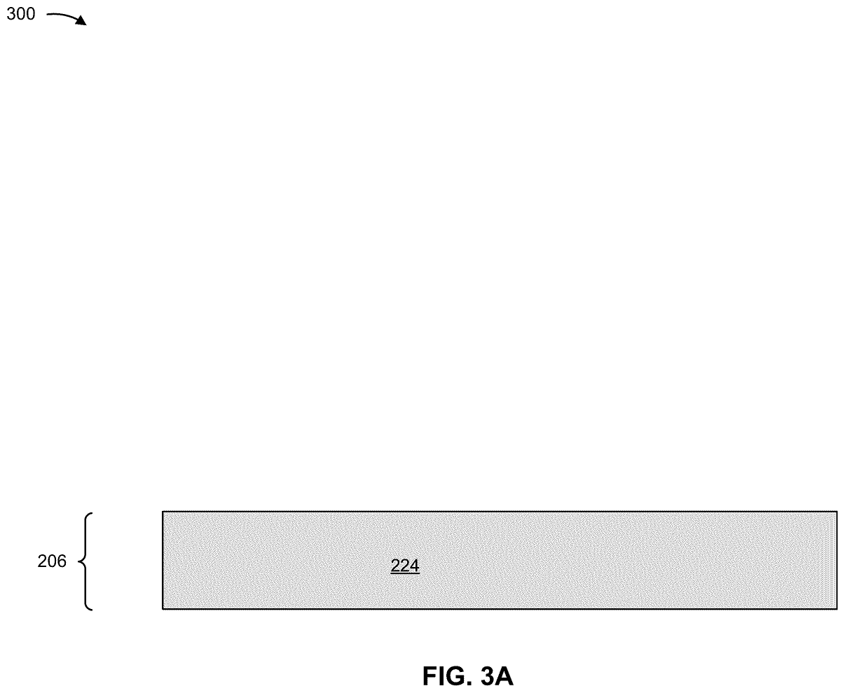

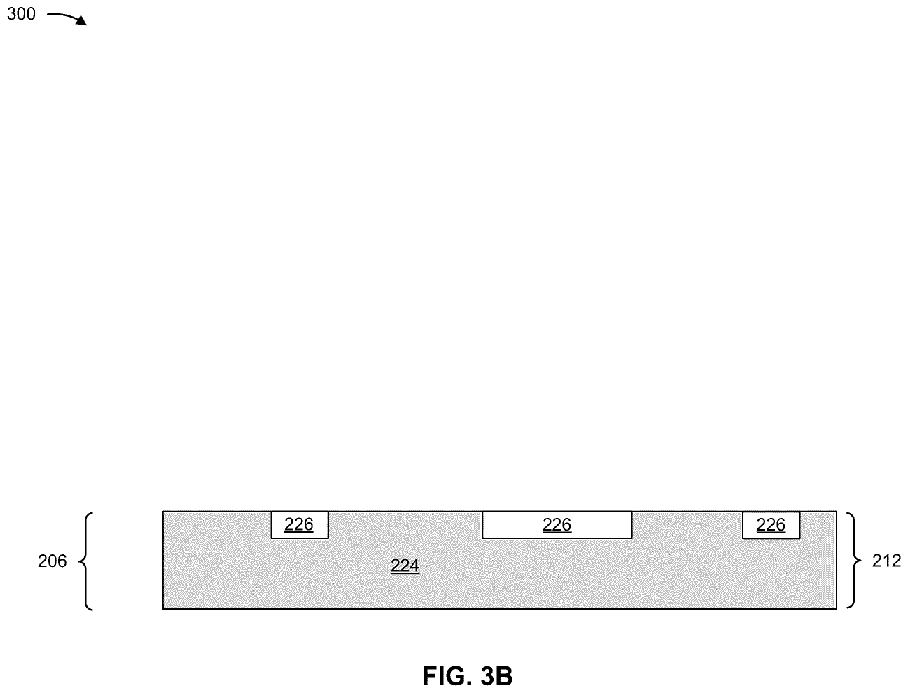

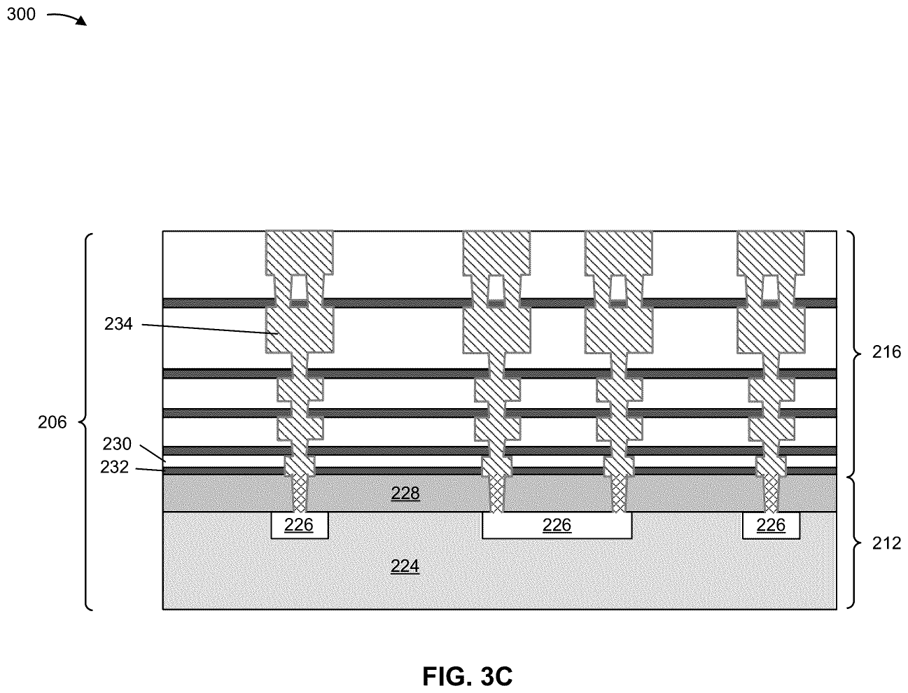

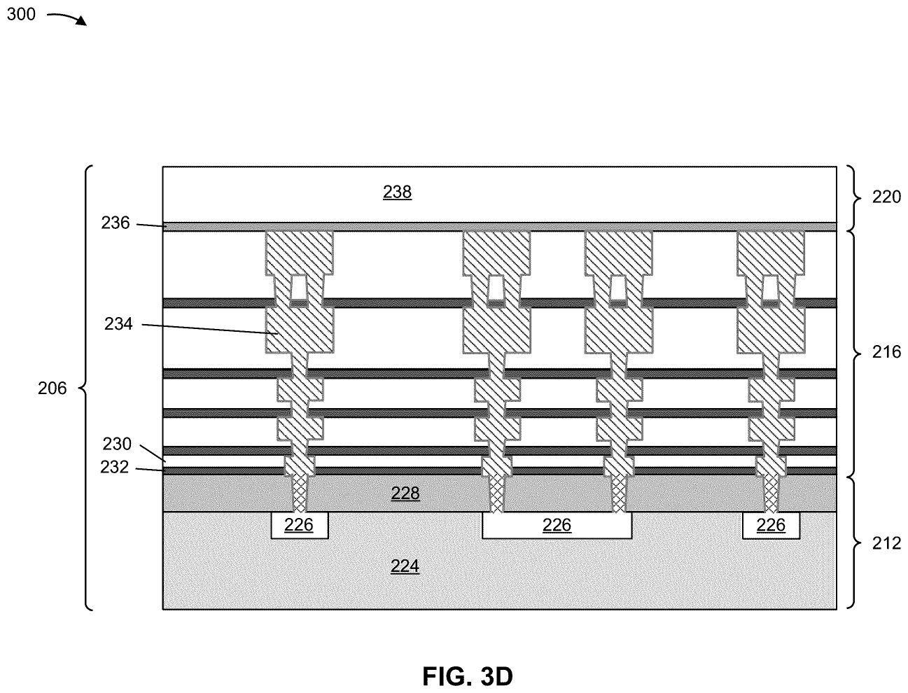

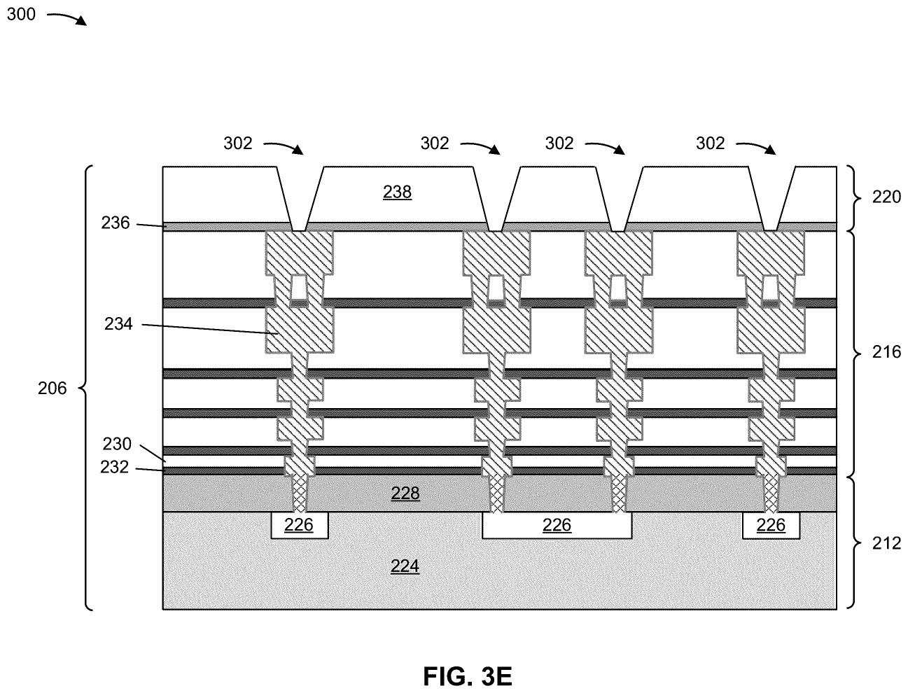

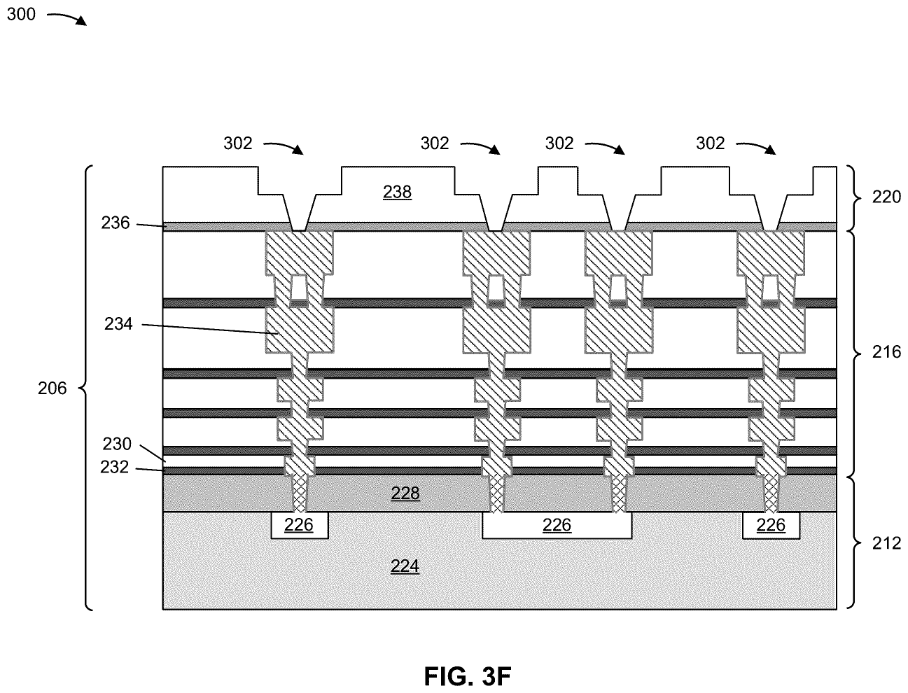

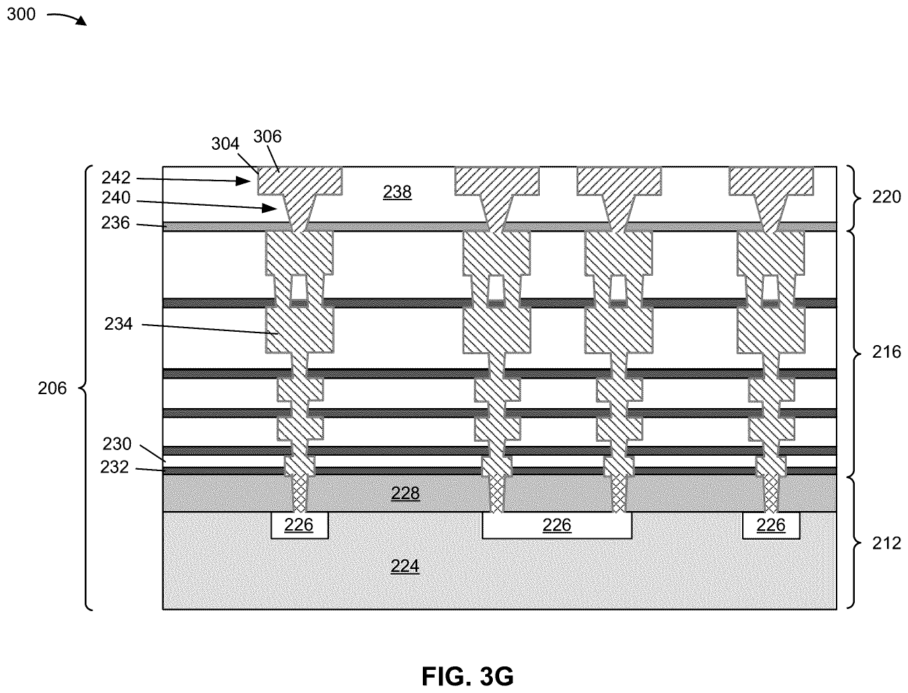

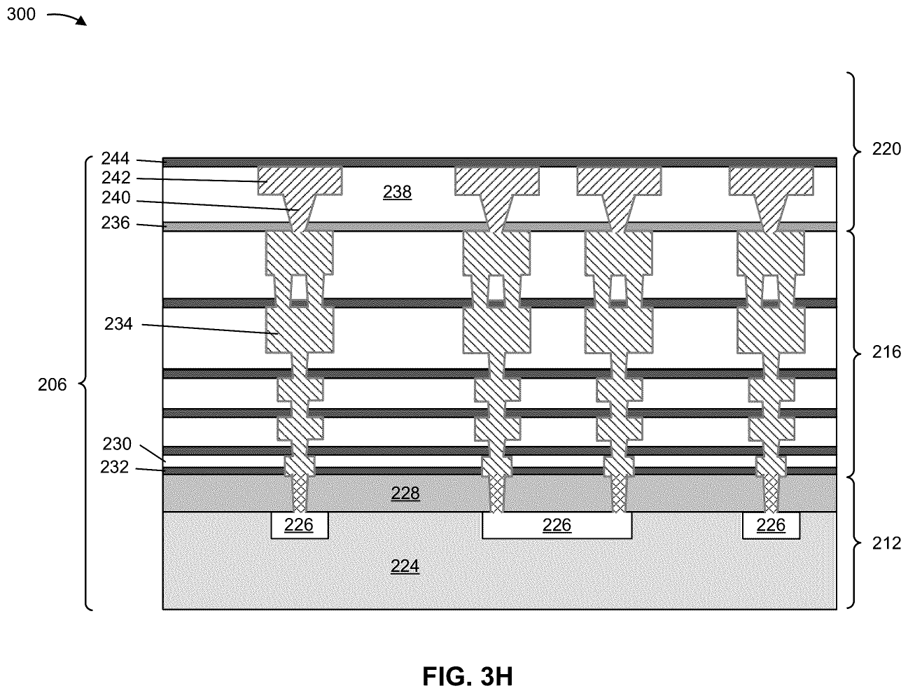

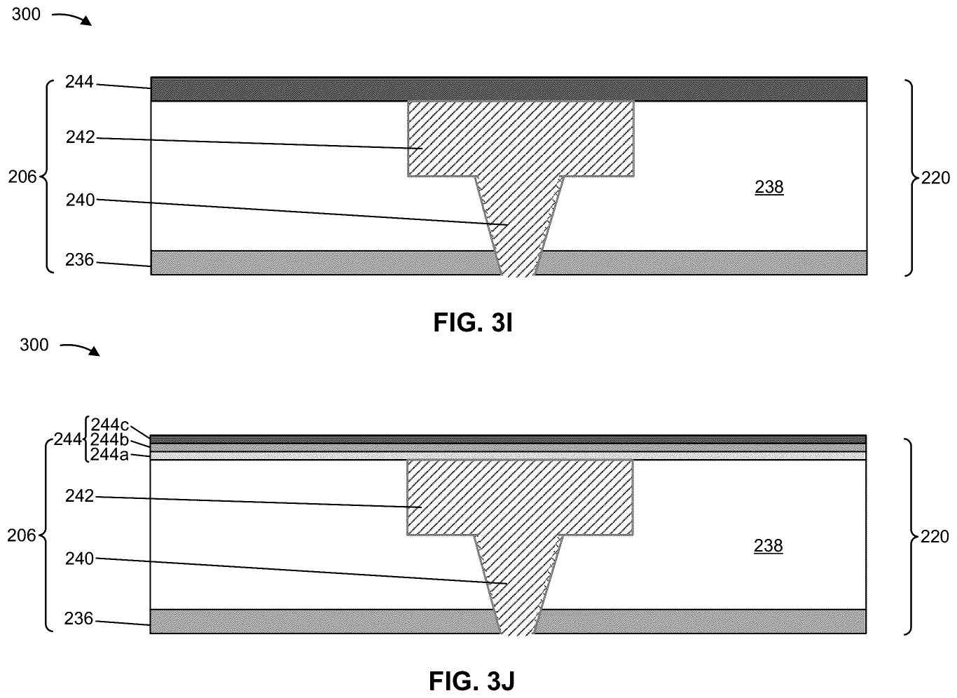

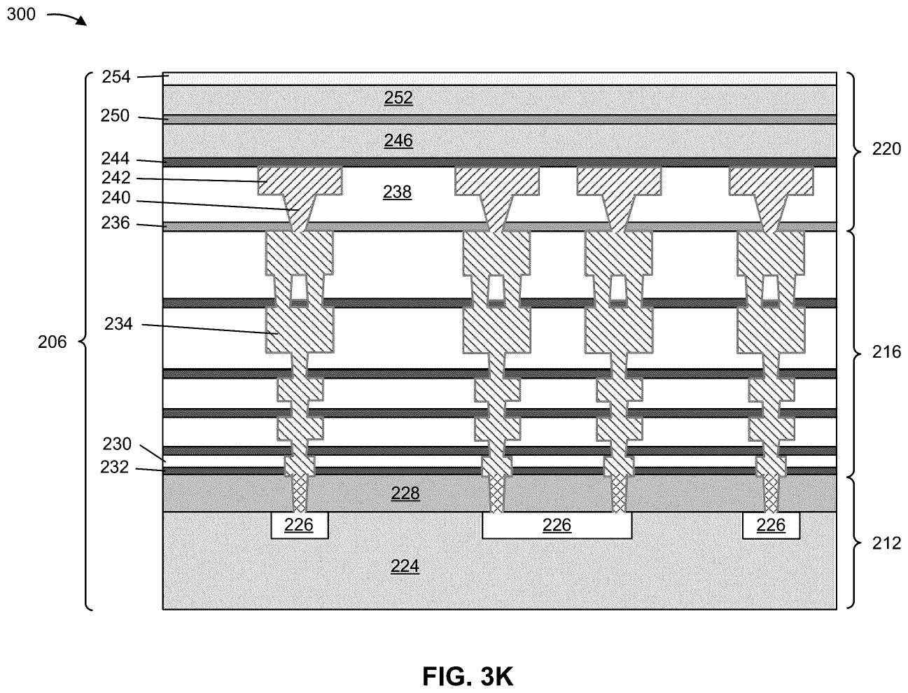

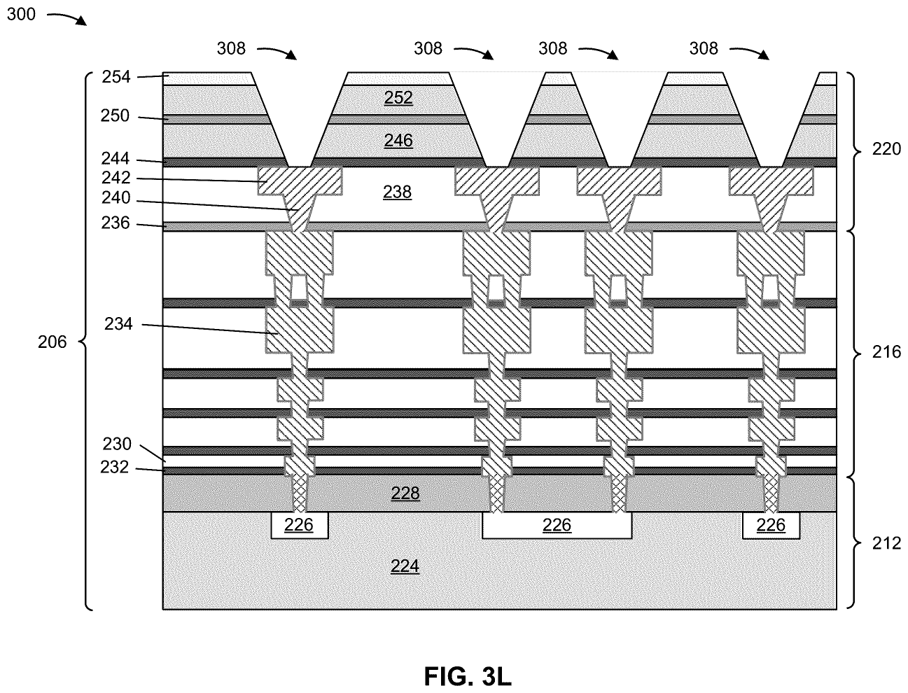

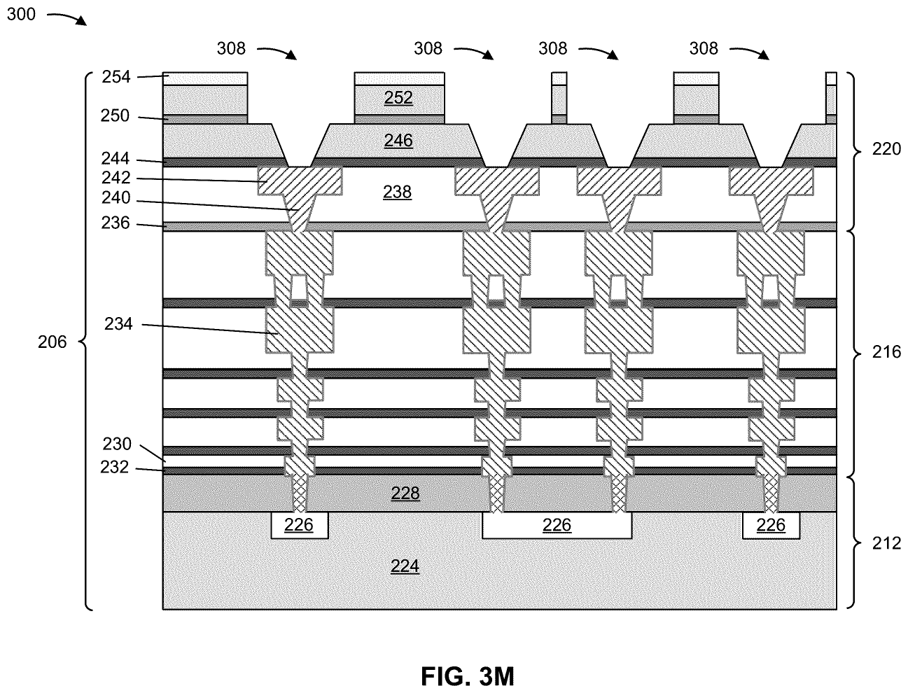

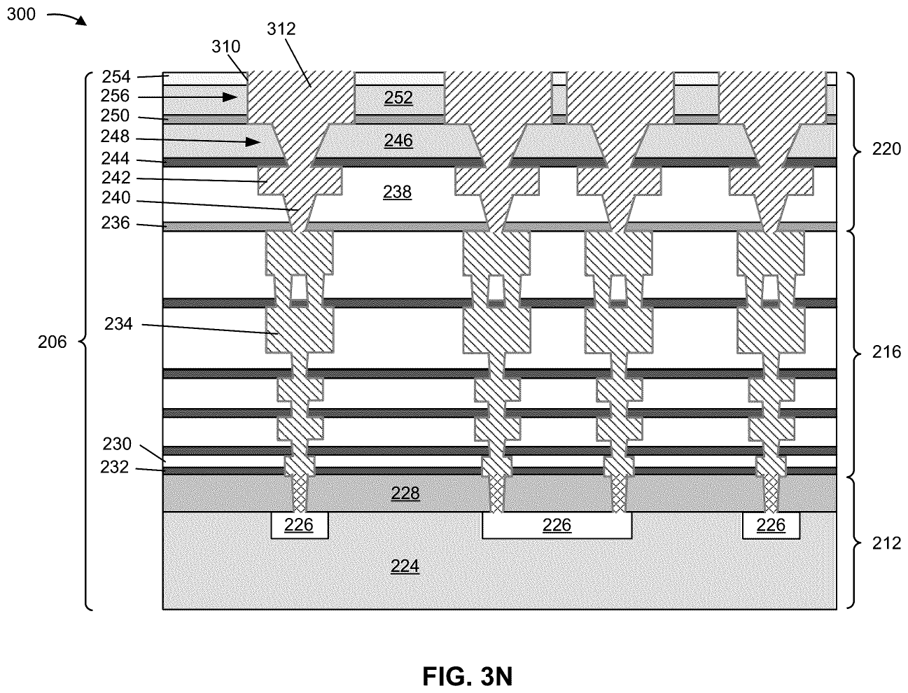

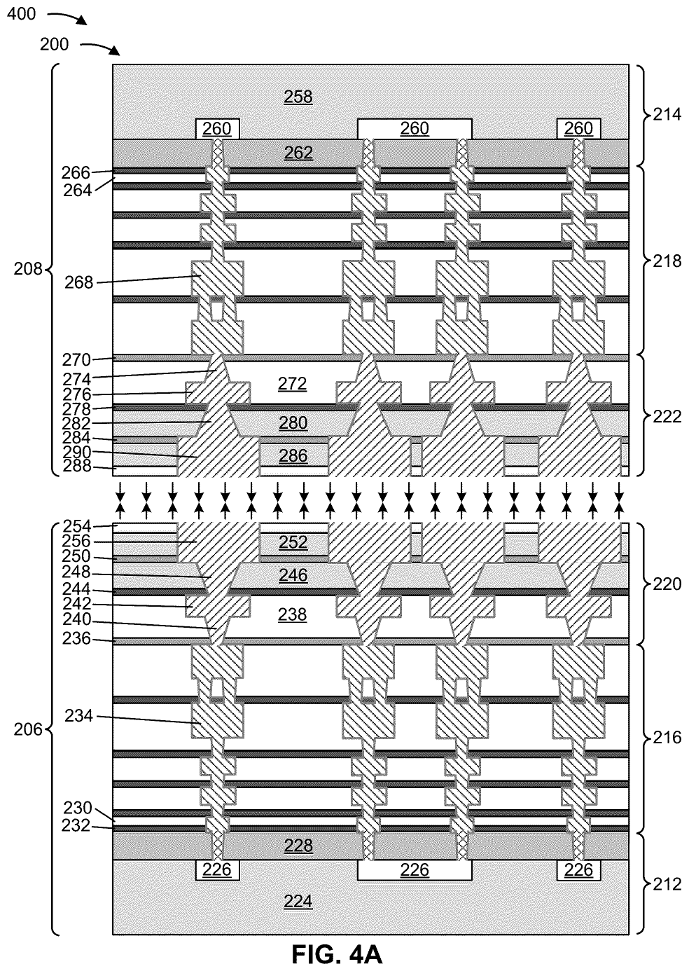

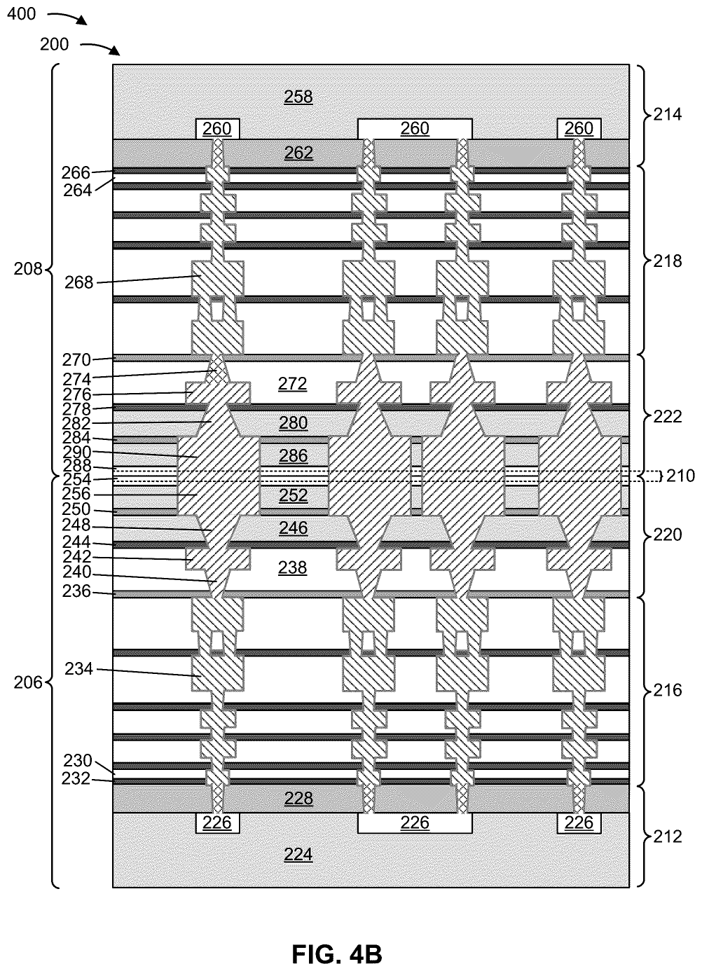

In some implementations, one or more of the semiconductor processing tools 102-116 and/or the wafer/die transport tool 116 may perform one or more semiconductor processing operations described herein. For example, one or more of the semiconductor processing tools 102-114 and/or the wafer/die transport tool 116 may form a first plurality of dielectric layers in an interconnect structure of a semiconductor device; may form a plurality of metallization layers in the first plurality of dielectric layers in the interconnect structure; may form an ELK dielectric layer, of a bonding region of the semiconductor device, above the first plurality of dielectric layers in the interconnect structure; may form a metal interconnect and a metal layer in the ELK dielectric layer; may form a silicon carbide (SiC) layer on the ELK dielectric layer and above the metal layer; may form a second plurality of dielectric layers over the silicon carbide layer; may form a recess through the second plurality of dielectric layers and through the silicon carbide layer to expose a top surface of the metal layer; and/or may form, in the recess, a bonding via on the metal layer, and a bonding pad on the bonding via, among other examples. In some implementations, one or more of the semiconductor processing tools 102-116 and/or the wafer/die transport tool 116 may perform one or more semiconductor processing operations described in connection with FIGS. 3A-3N, 4A, 4B, and/or 7, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

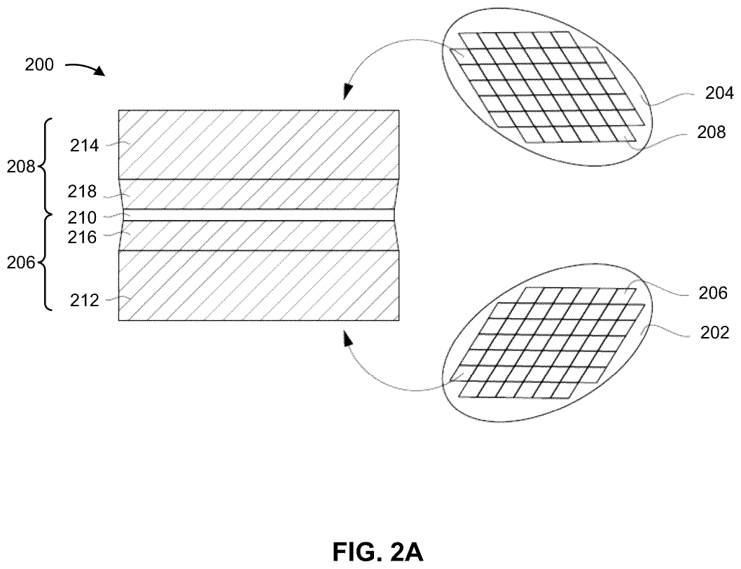

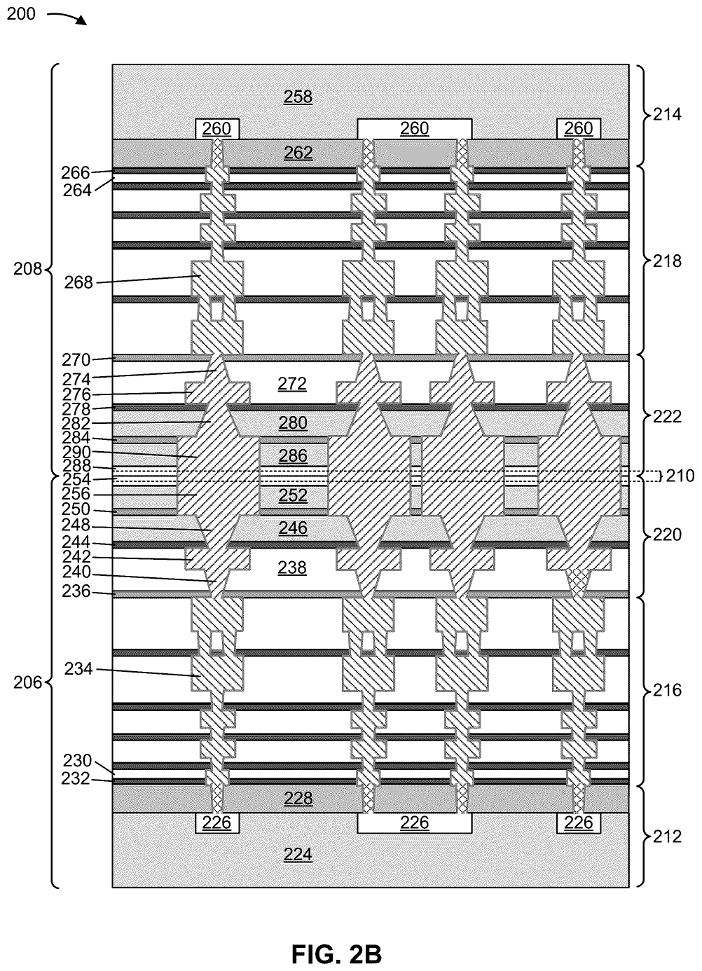

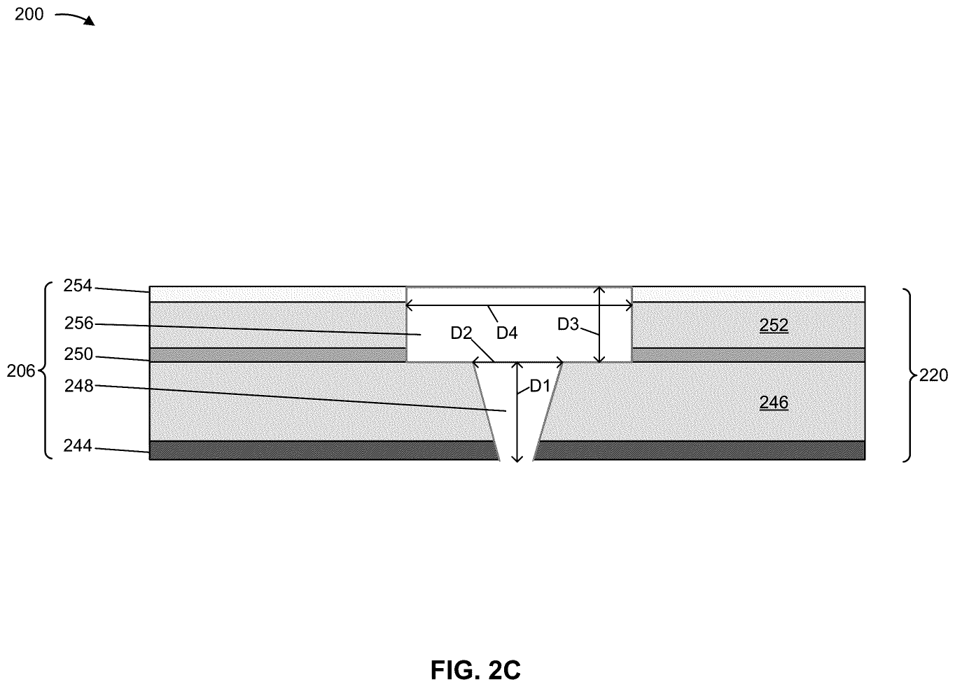

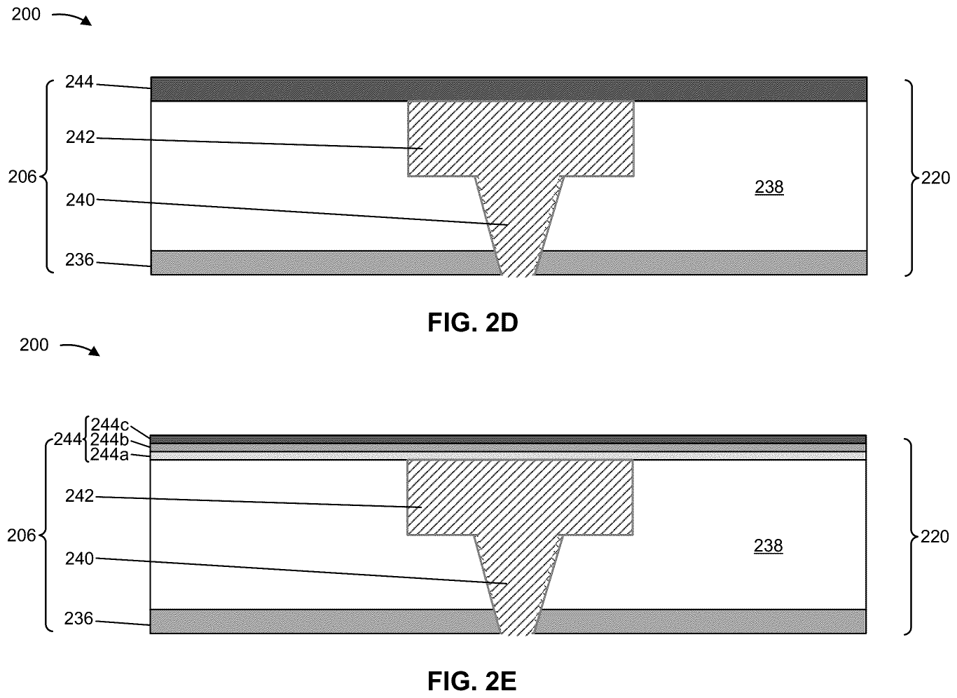

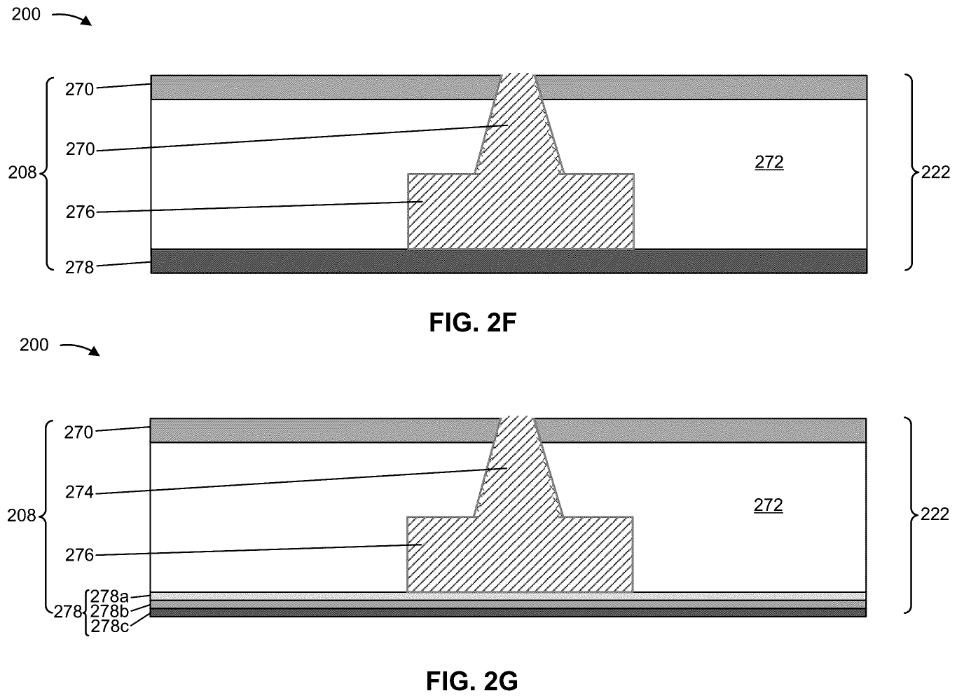

FIGS. 2A-2G are diagrams of examples of semiconductor devices 200 described herein. As shown in FIG. 2A, the semiconductor device 200 is formed by bonding a first semiconductor wafer 202 and a second semiconductor wafer 204. For example, a bonding tool 116 may be used to perform a bonding operation to bond the first semiconductor wafer 202 and the second semiconductor wafer 204 using a hybrid bonding technique, a direct bonding technique, a eutectic bonding technique, and/or another bonding technique. In the bonding operation, first semiconductor dies 206 on the first semiconductor wafer 202 are bonded with associated second semiconductor dies 208 on the second semiconductor wafer 204 to form semiconductor devices 200 (e.g., stacked semiconductor devices). The semiconductor devices 200 are then diced and packaged. Other processing steps may be performed to form the semiconductor devices 200.

As shown in FIG. 2A, the first semiconductor die 206 and the second semiconductor die 208 may be bonded at a bonding interface 210 such that the first semiconductor die 206 and the second semiconductor die 208 are stacked or vertically arranged in the semiconductor device 200. The first semiconductor die 206 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the first semiconductor die 206 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The second semiconductor die 208 may include the same type of semiconductor die as the first semiconductor die 206, or may include a different type of semiconductor die.

As further shown in FIG. 2A, the first semiconductor die 206 may include a device layer 212, and the second semiconductor die 208 may include a device layer 214. The first semiconductor die 206 may include an interconnect structure 216 above the device layer 212. The second semiconductor die 208 may include an interconnect structure 218 below the device layer 214. The bonding interface 210 may be located between the interconnect structures 216 and 218.

FIG. 2B illustrates a cross-sectional view of the semiconductor device 200 in which the details of the device layers 212 and 214, and the details of the interconnect structures 216 and 218 are shown. FIG. 2B further illustrates details of a bonding region 220 of the first semiconductor die 206 and a bonding region 222 of the second semiconductor die 208. The bonding region 220 may be included above the interconnect structure 216 of the first semiconductor die 206, and the bonding region 222 may be included below the interconnect structure 218 of the second semiconductor die 208. The bonding interface 210 may be located between the bonding region 220 and the bonding region 222.

As shown in FIG. 2B, the device layer 212 of the first semiconductor die 206 includes a substrate 224. The substrate 224 corresponds to a portion of the first semiconductor wafer 202 on which the first semiconductor die 206 is formed. The substrate 224 includes a silicon (Si) substrate, a substrate formed of a material including silicon, a III-V compound semiconductor material substrate such as gallium arsenide (GaAs), a silicon on insulator (SOI) substrate, or another type of semiconductor substrate.

The first semiconductor die 206 includes a device layer 212 in the substrate 224 and/or on the substrate. The device layer 212 may include active device(s), such as transistor(s), or passive device(s), such as lightguide(s), among other examples. Semiconductor devices 226 are included in and/or on the substrate 224 in the device layer 212 of the first semiconductor die 206. The semiconductor devices 226 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

A dielectric layer 228 is included over the substrate 224. The dielectric layer 228 includes an interlayer dielectric (ILD) layer, an etch stop layer (ESL), and/or another type of dielectric layer. The dielectric layer 228 includes dielectric material(s) that enable various portions of the substrate 224 and/or the semiconductor devices 226 to be selectively etched or protected from etching, and/or to electrically isolate the semiconductor devices 226 in the FEOL. The dielectric layer 228 includes a silicon nitride (SiₓN_{y}), an oxide (e.g., a silicon oxide (SiOₓ) and/or another oxide material), and/or another type of dielectric material.

An interconnect structure 216 of the first semiconductor die 206 is included above the substrate 224 and above the semiconductor devices 226. In some implementations, one or more semiconductor devices 226 are included in the interconnect structure 216 (e.g., a BEOL memory device, a BEOL resistor, a BEOL capacitor, a radio frequency (RF) switch, an optical modulator, a waveguide). The interconnect structure 216 includes a plurality of dielectric layers that are arranged in a direction that is approximately perpendicular to the substrate 224. The dielectric layers may include ILD layers 230 and ESLs 232 that are arranged in an alternating manner. The ILD layers 230 may each include an oxide (e.g., a silicon oxide (SiOₓ) and/or another oxide material), an undoped silicate glass (USG), a boron-containing silicate glass (BSG), a fluorine-containing silicate glass (FSG), and/or another suitable dielectric material. In some implementations, an ILD layer 230 includes an ELK dielectric material having a dielectric constant that is less than approximately 2.5. The ESLs 232 may each include a silicon nitride (SiₓN_{y}), silicon carbide (SiC), silicon oxynitride (SiON), and/or another suitable dielectric material. In some implementations, an ILD layer 230 and an ESL 232 include different dielectric materials to provide etch selectivity to enable various structures to be formed in the interconnect structure 216.

The interconnect structure 216 includes a plurality of metallization layers 234. The metallization layers 234 are electrically coupled and/or physically coupled with one or more of the semiconductor devices 226 in the device layer 212 and/or in the interconnect structure 216. The metallization layers 234 correspond to circuitry that enables signals and/or power to be provided to and/or from the semiconductor devices 226. The metallization layers 234 each include vias, trenches, contacts, plugs, interconnects, and/or other types of conductive structures. The metallization layers 234 each include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In some implementations, the metallization layers 234 of the interconnect structure 216 may be arranged in in a vertical manner. In other words, a plurality of stacked metallization layers 234 extend between the device layer 212 and the bonding region 220 to facilitate electrical signals and/or power to be routed between the device layer 212 and the second semiconductor die 208. The plurality of stacked metallization layers 234 may be referred to as M-layers. For example, a metal-0 (M0) layer may located at the bottom of the interconnect structure 216 and may be directly coupled with the device layer 212 (e.g., with the contacts or interconnects of the semiconductor devices 226 in the device layer 212), a metal-1 layer (M1) layer may be located above the M0 layer in the interconnect structure 216, a metal-2 layer (M2) layer may be located above the M1 layer, and so on. In some implementations, the interconnect structure 216 includes nine (9) stacked metallization layers 234 (e.g., M0-M8). In some implementations, the interconnect structure 216 includes another quantity of stacked metallization layers 234.

As further shown in FIG. 2B, the bonding region 220 may include a nitride layer 236 over and/or on the interconnect structure 216, and an ELK dielectric layer 238 over and/or on the nitride layer 236. The nitride layer 236 includes a silicon nitride (SiₓN_{y} such as Si₃N₄), a silicon oxynitride (SiON), a silicon carbon nitride (SiCN), a silicon oxycarbonitride (SiOCN), and/or another nitride-containing dielectric material. The ELK dielectric layer 238 includes one or more dielectric materials having a dielectric constant (k) that is less than approximately 2.5. In some implementations, ELK dielectric materials for the ELK dielectric layer 238 include carbon doped silicon oxide (C—SiOₓ), amorphous fluorinated carbon (a-CₓF_{y}), parylene, bis-benzocyclobutenes (BCB), polytetrafluoroethylene (PTFE), and/or a silicon oxycarbide (SiOC) polymer. In some implementations, the ELK dielectric material(s) for the ELK dielectric layer 238 include porous hydrogen silsesquioxane (HSQ), porous methyl silsesquioxane (MSQ), porous polyarylether (PAE), and/or porous silicon oxide (SiOₓ), among other examples. The ELK dielectric material(s) of the ELK dielectric layer 238 has a lower dielectric constant than other dielectric layers (e.g., USG, silicon oxide) and enables lower RC delays to be achieved for metallization layers in the bonding region 220 relative to the other dielectric layers. The lower RC delays may enable faster signal propagation in and/or through the bonding region 220.

Metal interconnects 240 are included in and/or extend through the nitride layer 236 and the ELK dielectric layer 238. The metal interconnects 240 are electrically coupled and/or physically coupled with one or more metallization layers 234 in the interconnect structure 216. Metal layers 242 are electrically coupled and/or physically coupled with the metal interconnects 240. The metal layers 242 are also included in the ELK dielectric layer 238.

A carbide layer 244 is included over and/or on the ELK dielectric layer 238, and a dielectric layer 246 is included over and/or on the carbide layer 244. bonding vias 248 extend through and/or are included in the carbide layer 244 and the dielectric layer 246. The bonding vias 248 are electrically coupled and/or physically coupled with the metal layers 242. The carbide layer 244 may be included in the bonding region 220 as an ESL. The carbide layer 244 includes a carbon-containing dielectric material such as silicon carbide (SiC). The carbon-containing dielectric material of the carbide layer 244 is harder than other dielectric materials such as silicon nitride (SiₓN_{y}) and silicon oxide (SiOₓ), which provides a closer match of thermal expansion and contraction coefficients between the carbide layer 244 and the bonding vias 248 than other dielectric materials. Moreover, the carbon-containing dielectric material of the carbide layer 244 reduces the likelihood of discontinuity formation (e.g., voids, cracks, delamination, peeling) in the bonding vias 248 because of the increased adhesion with the metal material(s) (e.g., copper (Cu) and/or another metal material) of the bonding vias 248 relative to other dielectric materials. In addition, the carbon-containing dielectric material of the carbide layer 244 reduces the likelihood of discontinuity formation in the bonding vias 248 because of the increased adhesion with the ELK dielectric material(s) of the ELK dielectric layer 238 relative to other dielectric materials.

The dielectric layer 246 includes a high density plasma (HDP) dielectric material and/or another suitable dielectric material. The bonding vias 248 each includes a via, an interconnect, a conductive column, a plug, and/or another type of conductive structure. The bonding vias 248 each includes one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

A nitride layer 250 is included over and/or on the dielectric layer 246, a dielectric layer 252 is included over and/or on the nitride layer 250, and a bonding dielectric layer 254 is included over and/or on the dielectric layer 252. Bonding pads 256 extend through and/or are included in the nitride layer 250, the dielectric layer 252, and the bonding dielectric layer 254. The nitride layer 250 may be included in the bonding region 220 as an ESL. The nitride layer 250 includes a nitride-containing dielectric material such as a silicon nitride (SiₓN_{y} such as Si₃N₄) a silicon oxynitride (SiON), a silicon carbon nitride (SiCN), a silicon oxycarbonitride (SiOCN), and/or another nitride-containing dielectric material. The dielectric layer 246 includes an HDP dielectric material and/or another suitable dielectric material. The bonding dielectric layer 254 may include a silicon oxynitride (SiON) and/or another suitable bonding dielectric material.

The HBL structures 256 are electrically coupled and/or physically coupled with the bonding vias 248. The bonding pads 256 each includes a trench, a pad, a contact, and/or another type of conductive bonding structure. The bonding pads 256 each includes one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

As further shown in FIG. 2B, the device layer 214 of the second semiconductor die 208 includes a substrate 258. The substrate 258 corresponds to a portion of the second semiconductor wafer 204 on which the second semiconductor die 208 is formed. The substrate 258 includes a silicon (Si) substrate, a substrate formed of a material including silicon, a III-V compound semiconductor material substrate such as gallium arsenide (GaAs), a silicon on insulator (SOI) substrate, or another type of semiconductor substrate.

Semiconductor devices 260 are included in and/or under the substrate 258 in the device layer 214 of the second semiconductor die 208. The semiconductor devices 260 include transistors (e.g., planar transistors, finFETs, GAA transistors), pixel sensors, capacitors, resistors, inductors, photodetectors, transceivers, transmitters, receives, optical circuits, and/or other types of semiconductor devices.

A dielectric layer 262 is included under the substrate 258. The dielectric layer 262 includes an ILD layer, an ESL, and/or another type of dielectric layer. The dielectric layer 262 includes dielectric material(s) that enable various portions of the substrate 258 and/or the semiconductor devices 260 to be selectively etched or protected from etching, and/or to electrically isolate the semiconductor devices 260 in the FEOL. The dielectric layer 262 includes a silicon nitride (SiₓN_{y}), an oxide (e.g., a silicon oxide (SiOₓ) and/or another oxide material), and/or another type of dielectric material.

An interconnect structure 218 of the second semiconductor die 208 is included below and/or under the substrate 258 and below the semiconductor devices 260. In some implementations, one or more semiconductor devices 260 are included in the interconnect structure 218 (e.g., a BEOL memory device, a BEOL resistor, a BEOL capacitor, a radio frequency (RF) switch, an optical modulator, a waveguide). The interconnect structure 218 includes a plurality of dielectric layers that are arranged in a direction that is approximately perpendicular to the substrate 258. The dielectric layers may include ILD layers 264 and ESLs 266 that are arranged in an alternating manner. The ILD layers 264 may each include an oxide (e.g., a silicon oxide (SiOₓ) and/or another oxide material), a USG, a BSG, an FSG, and/or another suitable dielectric material. In some implementations, an ILD layer 264 includes an ELK dielectric material having a dielectric constant that is less than approximately 2.5. The ESLs 266 may each include a silicon nitride (SiₓN_{y}), silicon carbide (SiC), silicon oxynitride (SiON), and/or another suitable dielectric material. In some implementations, an ILD layer 264 and an ESL 266 include different dielectric materials to provide etch selectivity to enable various structures to be formed in the interconnect structure 218.

The interconnect structure 218 includes a plurality of metallization layers 268. The metallization layers 268 are electrically coupled and/or physically coupled with one or more of the semiconductor devices 260 in the device layer 214 and/or in the interconnect structure 218. The metallization layers 268 correspond to circuitry that enables signals and/or power to be provided to and/or from the semiconductor devices 260. The metallization layers 268 each includes vias, trenches, contacts, plugs, interconnects, and/or other types of conductive structures. The metallization layers 268 each includes one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials.

In some implementations, the metallization layers 268 of the interconnect structure 218 may be arranged in in a vertical manner. In other words, a plurality of stacked metallization layers 268 extend between the device layer 214 and the bonding region 222 to facilitate electrical signals and/or power to be routed between the device layer 214 and the first semiconductor die 206. The plurality of stacked metallization layers 268 may be referred to as M-layers. In some implementations, the interconnect structure 218 includes nine (9) stacked metallization layers 268 (e.g., M0-M8). In some implementations, the interconnect structure 218 includes another quantity of stacked metallization layers 268.

As further shown in FIG. 2B, the bonding region 222 may include a nitride layer 270 below and/or under the interconnect structure 218, and an ELK dielectric layer 272 below and/or under the nitride layer 270. The nitride layer 270 includes a silicon nitride (SiₓN_{y} such as Si₃N₄) a silicon oxynitride (SiON), a silicon carbon nitride (SiCN), a silicon oxycarbonitride (SiOCN), and/or another nitride-containing dielectric material. The ELK dielectric layer 272 includes one or more dielectric materials having a dielectric constant (k) that is less than approximately 2.5. In some implementations, ELK dielectric materials for the ELK dielectric layer 238 include carbon doped silicon oxide (c-SiOₓ), amorphous fluorinated carbon (a-CₓF_{y}), parylene, BCB, PTFE, and/or a silicon oxycarbide (SiOC) polymer. In some implementations, the ELK dielectric material(s) for the ELK dielectric layer 272 include porous HSQ, porous MSQ, porous PAE, and/or porous silicon oxide (SiOₓ), among other examples. The ELK dielectric material(s) of the ELK dielectric layer 272 has a lower dielectric constant than other dielectric layers (e.g., USG, silicon oxide) and enables lower RC delays to be achieved for metallization layers in the bonding region 222 relative to the other dielectric layers. The lower RC delays may enable faster signal propagation in and/or through the bonding region 222.

Metal interconnects 274 may be included in and/or may extend through the nitride layer 270 and the ELK dielectric layer 272. The metal interconnects 274 are electrically coupled and/or physically coupled with one or more metallization layers 268. Metal layers 276 are electrically coupled and/or physically coupled with the metal interconnects 274. The metal layers 276 are also included in the ELK dielectric layer 272.

A carbide layer 278 is included below and/or under the ELK dielectric layer 272, and a dielectric layer 280 is included below and/or under the carbide layer 278. Bonding vias 282 extend through and/or are included in the carbide layer 278 and the dielectric layer 280. The bonding vias 282 are electrically coupled and/or physically coupled with the metal layers 276. The carbide layer 278 may be included in the bonding region 222 as an ESL. The carbide layer 278 includes a carbon-containing dielectric material such as silicon carbide (SIC). The carbon-containing dielectric material of the carbide layer 278 is harder than other dielectric materials such as silicon nitride (SiₓN_{y}) and silicon oxide (SiOₓ), which provides a closer match of thermal expansion and contraction coefficients between the carbide layer 278 and the bonding vias 282 than other dielectric materials. Moreover, the carbon-containing dielectric material of the carbide layer 278 reduces the likelihood of discontinuity formation (e.g., voids, cracks, delamination, peeling) in the bonding vias 282 because of the increased adhesion with the metal material(s) (e.g., copper (Cu) and/or another metal material) of the bonding vias 282 relative to other dielectric materials. In addition, the carbon-containing dielectric material of the carbide layer 278 reduces the likelihood of discontinuity formation in the bonding vias 282 because of the increased adhesion with the ELK dielectric material(s) of the ELK dielectric layer 272 relative to other dielectric materials.

The dielectric layer 280 includes an HDP dielectric material and/or another suitable dielectric material. The bonding vias 282 each includes a via, an interconnect, a conductive column, a plug, and/or another type of conductive structure. The bonding vias 282 each includes one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

A nitride layer 284 is included below and/or under the dielectric layer 280, a dielectric layer 286 is included below and/or under the nitride layer 284, and a bonding dielectric layer 288 is included below and/or under the dielectric layer 286. Bonding pads 290 extend through and/or are included in the nitride layer 284, the dielectric layer 286, and the bonding dielectric layer 288. The nitride layer 284 may be included in the bonding region 222 as an ESL. The nitride layer 284 includes a nitride-containing dielectric material such as a silicon nitride (SiₓN_{y} such as Si₃N₄) a silicon oxynitride (SiON), a silicon carbon nitride (SiCN), a silicon oxycarbonitride (SiOCN), and/or another nitride-containing dielectric material. The dielectric layer 286 includes an HDP dielectric material and/or another suitable dielectric material. The bonding dielectric layer 288 may include a silicon oxynitride (SiON) and/or another suitable bonding dielectric material.

The bonding pads 290 are electrically coupled and/or physically coupled with the bonding vias 282. The bonding pads 290 each includes a trench, a pad, a contact, and/or another type of conductive bonding structure. The bonding pads 290 each includes one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

At the bonding interface 210, the bonding dielectric layer 254 and the bonding dielectric layer 288 are bonded by a dielectric-to-dielectric bond. The bonding pads 256 and the bonding pads 290 are bonded by a metal-to-metal bond. The combination of the dielectric-to-dielectric bond and the metal-to-metal bond is referred to as a hybrid bond.

FIG. 2C illustrates one or more dimensions of an bonding vias 248 and/or of a bonding pad 256 described herein. Additionally and/or alternatively, the one or more dimensions illustrated in FIG. 2C are dimensions of an bonding vias 282 and/or of a bonding pad 290. The one or more dimensions may include a dimension D1, a dimension D2, a dimension D3, and/or a dimension D4, among other examples.

The dimension D1 may correspond to a depth or a thickness of a bonding via 248 (and/or of a bonding via 282). In some implementations, the dimension D1 is included in a range of approximately 0.1 microns to approximately 0.5 microns. If the dimension D1 is less than approximately 0.1 microns, the resistivity of the HBC structure 248 may be increased. If the dimension D1 is greater than approximately 0.5 microns, the power efficiency may be reduced for the semiconductor device 200, resulting in increased power consumption for the semiconductor device 200. If the dimension D1 is approximately 0.1 microns to approximately 0.5 microns, a sufficiently low resistivity and power consumption may be achieved for the semiconductor device 200. However, other values for the dimension D1, and/or ranges other than approximately 0.1 microns to approximately 0.5 microns, are within the scope of the present disclosure.

The dimension D2 may correspond to a top width of a bonding vias 248 (and/or of a bonding vias 282). In some implementations, the dimension D2 is included in a range of approximately 0.2 microns to approximately 0.8 microns. If the dimension D2 is less than approximately 0.2 microns, the resistivity of the bonding via 248 may be increased. If the dimension D2 is greater than approximately 0.8 microns, the power efficiency may be reduced for the semiconductor device 200, resulting in increased power consumption for the semiconductor device 200. If the dimension D2 is approximately 0.2 microns to approximately 0.8 microns, a sufficiently low resistivity and power consumption may be achieved for the semiconductor device 200. However, other values for the dimension D2, and/or ranges other than approximately 0.2 microns to approximately 0.8 microns, are within the scope of the present disclosure.

The dimension D3 may correspond to a depth or a thickness of a bonding pad 256 (and/or of a bonding pad 290). In some implementations, the dimension D3 is included in a range of approximately 0.6 microns to approximately 1.8 microns. If the dimension D3 is less than approximately 0.6 microns, the resistivity of the bonding pad 256 may be increased. If the dimension D3 is greater than approximately 1.8 microns, the power efficiency may be reduced for the semiconductor device 200, resulting in increased power consumption for the semiconductor device 200. If the dimension D3 is approximately 0.6 microns to approximately 1.8 microns, a sufficiently low resistivity and power consumption may be achieved for the semiconductor device 200. However, other values for the dimension D3, and/or ranges other than approximately 0.6 microns to approximately 1.8 microns, are within the scope of the present disclosure.

The dimension D4 may correspond to a top width of a bonding pad 256 (and/or of a bonding pad 290). In some implementations, the dimension D4 is included in a range of approximately 0.5 microns to approximately 2 microns. If the dimension D4 is less than approximately 0.5 microns, the resistivity of the bonding pad 256 may be increased. If the dimension D4 is greater than approximately 2 microns, the power efficiency may be reduced for the semiconductor device 200, resulting in increased power consumption for the semiconductor device 200. If the dimension D4 is approximately 0.5 microns to approximately 2 microns, a sufficiently low resistivity and power consumption may be achieved for the semiconductor device 200. However, other values for the dimension D4, and/or ranges other than approximately 0.5 microns to approximately 2 microns, are within the scope of the present disclosure.

In some implementations, a ratio of the dimension D2 to the dimension D1 is included in a range of approximately 0.4:1 to approximately 8:1. However, other values for the range are within the scope of the present disclosure. In some implementations, a ratio of the dimension D3 to the dimension D1 is included in a range of approximately 0.1:1 to approximately 1.3:1. However, other values for the range are within the scope of the present disclosure. In some implementations, a ratio of the dimension D3 to the dimension D2 is included in a range of approximately 0.7:1 to approximately 9:1. However, other values for the range are within the scope of the present disclosure. In some implementations, a ratio of the dimension D4 to the dimension D1 is included in a range of approximately 1:1 to approximately 20:1. However, other values for the range are within the scope of the present disclosure. In some implementations, a ratio of the dimension D4 to the dimension D2 is included in a range of approximately 0.6:1 to approximately 10:1. However, other values for the range are within the scope of the present disclosure. In some implementations, a ratio of the dimension D4 to the dimension D3 is included in a range of approximately 0.25:1 to approximately 3.33:1. However, other values for the range are within the scope of the present disclosure.

FIGS. 2D and 2E illustrate example implementations of the carbide layer 244. FIG. 2D illustrates an example implementation in which the carbide layer 244 is a single-layer structure. The single-layer structure includes a layer of silicon carbide (SiC) with other elements such as nitrogen (N), hydrogen (H), and/or oxygen (O), among other examples. The carbon (C) concentration in the single-layer structure may be at least 5% by weight of the material of the single-layer structure or greater to provide sufficient hardness and durability for the carbide layer 244.

FIG. 2E illustrates an example implementation in which the carbide layer 244 is a multiple-layer structure that includes a plurality of sub-layers. For example, the multiple-layer structure of the carbide layer 244 may include a first sub-layer 244a over and/or on the ELK dielectric layer 238, a second sub-layer 244b over and/or on the first sub-layer 244a, and a third sub-layer 244c over and/or on the second sub-layer 244b. In some implementations, the multiple-layer structure includes another quantity and/or arrangement of sub-layers. The sub-layers of the multiple-layer structure may have an increasing concentration of carbon. For example, the first sub-layer 244a may have a first carbon concentration, the second sub-layer 244b may have a second carbon concentration that is greater than the first carbon concentration, and the third sub-layer 244c may have a third carbon concentration that is greater than the second carbon concentration. Having a greater concentration of carbon at the top of the multiple-layer structure provides a hard top surface for the carbide layer 244, which enables the carbide layer 244 to better withstand planarization during semiconductor processing of the first semiconductor die 206. Having a lesser concentration of carbon (and thus, a greater concentration of nitrogen, hydrogen, and/or oxygen) at the bottom of the multiple-layer structure promotes adhesion between the carbide layer 244 and the ELK dielectric layer 238.

In some implementations, the first carbon concentration of the first sub-layer 244a is included in a range of greater than 0% by weight of the first sub-layer 244a to approximately 10% by weight of the first sub-layer 244a. If the first carbon concentration of the first sub-layer 244a is 0%, the first sub-layer 244a may not provide etch selectivity relative to the ELK dielectric layer 238. If the first carbon concentration of the first sub-layer 244a is greater than approximately 10% by weight of the first sub-layer 244a, the first sub-layer 244a may not be able to sufficiently adhere to the ELK dielectric layer 238. If the first carbon concentration of the first sub-layer 244a is greater than 0% to approximately 10%, sufficient adhesion of the first sub-layer 244a to the ELK dielectric layer 238 and sufficient etch selectivity may be achieved. However, other values for the first carbon concentration of the first sub-layer 244a, and ranges other than greater than 0% to approximately 10%, are within the scope of the present disclosure.

In some implementations, the second carbon concentration of the second sub-layer 244b is included in a range of approximately 10% by weight of the second sub-layer 244b to approximately 60% by weight of the second sub-layer 244b. The second sub-layer 244b may not be able to sufficiently adhere to the first sub-layer 244a if the second carbon concentration of the second sub-layer 244b is less than approximately 10% or greater than approximately 60%. Sufficient adhesion may be achieved if the second carbon concentration of the second sub-layer 244b is approximately 10% to approximately 60%. However, other values for the second carbon concentration of the second sub-layer 244b, and ranges other than approximately 10% to approximately 60%, are within the scope of the present disclosure.

In some implementations, the third carbon concentration of the third sub-layer 244c is included in a range of approximately 60% by weight of the third sub-layer 244c to approximately 80% by weight of the third sub-layer 244c. If the third carbon concentration of the third sub-layer 244c is less than approximately 60%, the third sub-layer 244c may not have sufficient hardness to withstand planarization. If the third carbon concentration of the third sub-layer 244c is greater than approximately 80% by weight of the third sub-layer 244c, the third sub-layer 244c may not be able to sufficiently adhere to the second sub-layer 244b. If the third carbon concentration of the third sub-layer 244c is approximately 60% to approximately 80%, sufficient adhesion of the third sub-layer 244c to the second sub-layer 244b and sufficient hardness to withstand planarization may be achieved. However, other values for the third carbon concentration of third sub-layer 244c, and ranges other than approximately 60% to approximately 80%, are within the scope of the present disclosure.

FIGS. 2F and 2G illustrate example implementations of the carbide layer 278. FIG. 2F illustrates an example implementation in which the carbide layer 278 is a single-layer structure. The single-layer structure includes a layer of silicon carbide (SiC) with other elements such as nitrogen (N), hydrogen (H), and/or oxygen (O), among other examples. The carbon (C) concentration in the single-layer structure may be at least 5% by weight of the material of the single-layer structure or greater to provide sufficient hardness and durability for the carbide layer 278.

FIG. 2G illustrates an example implementation in which the carbide layer 278 is a multiple-layer structure that includes a plurality of sub-layers. For example, the multiple-layer structure of the carbide layer 278 may include a first sub-layer 278a below and/or under the ELK dielectric layer 272, a second sub-layer 278b below and/or under the first sub-layer 278a, and a third sub-layer 278c below and/or under the second sub-layer 278b. In some implementations, the multiple-layer structure includes another quantity and/or arrangement of sub-layers. The sub-layers of the multiple-layer structure may have an increasing concentration of carbon. For example, the first sub-layer 278a may have a first carbon concentration, the second sub-layer 278b may have a second carbon concentration that is greater than the first carbon concentration, and the third sub-layer 278c may have a third carbon concentration that is greater than the second carbon concentration. Having a greater concentration of carbon at the bottom of the multiple-layer structure provides a hard top surface for the carbide layer 278, which enables the carbide layer 278 to better withstand planarization during semiconductor processing of the second semiconductor die 208. Having a lesser concentration of carbon (and thus, a greater concentration of nitrogen, hydrogen, and/or oxygen) at the top of the multiple-layer structure promotes adhesion between the carbide layer 278 and the ELK dielectric layer 272.

In some implementations, the first carbon concentration of the first sub-layer 278a is included in a range of greater than 0% by weight of the first sub-layer 278a to approximately 10% by weight of the first sub-layer 278a. If the first carbon concentration of the first sub-layer 278a is 0%, the first sub-layer 278a may not provide etch selectivity relative to the ELK dielectric layer 272. If the first carbon concentration of the first sub-layer 278a is greater than approximately 10% by weight of the first sub-layer 278a, the first sub-layer 278a may not be able to sufficiently adhere to the ELK dielectric layer 272. If the first carbon concentration of the first sub-layer 278a is greater than 0% to approximately 10%, sufficient adhesion of the first sub-layer 278a to the ELK dielectric layer 272 and sufficient etch selectivity may be achieved. However, other values for the first carbon concentration of the first sub-layer 278a, and ranges other than greater than 0% to approximately 10%, are within the scope of the present disclosure.

In some implementations, the second carbon concentration of the second sub-layer 278b is included in a range of approximately 10% by weight of the second sub-layer 278b to approximately 60% by weight of the second sub-layer 278b. The second sub-layer 278b may not be able to sufficiently adhere to the first sub-layer 278a if the second carbon concentration of the second sub-layer 278b is less than approximately 10% or greater than approximately 60%. Sufficient adhesion may be achieved if the second carbon concentration of the second sub-layer 278b is approximately 10% to approximately 60%. However, other values for the second carbon concentration of the second sub-layer 278b, and ranges other than approximately 10% to approximately 60%, are within the scope of the present disclosure.

In some implementations, the third carbon concentration of the third sub-layer 278c is included in a range of approximately 60% by weight of the third sub-layer 278c to approximately 80% by weight of the third sub-layer 278c. If the third carbon concentration of the third sub-layer 278c is less than approximately 60%, the third sub-layer 278c may not have sufficient hardness to withstand planarization. If the third carbon concentration of the third sub-layer 278c is greater than approximately 80% by weight of the third sub-layer 278c, the third sub-layer 278c may not be able to sufficiently adhere to the second sub-layer 278b. If the third carbon concentration of the third sub-layer 278c is approximately 60% to approximately 80%, sufficient adhesion of the third sub-layer 278c to the second sub-layer 278b and sufficient hardness to withstand planarization may be achieved. However, other values for the third carbon concentration of third sub-layer 278c, and ranges other than approximately 60% to approximately 80%, are within the scope of the present disclosure.

As indicated above, FIGS. 2A-2G are provided as examples. Other examples may differ from what is described with regard to FIGS. 2A-2G.

FIGS. 3A-3N are diagrams of an example implementation 300 of forming a semiconductor die described herein. In some implementations, one or more of the semiconductor processing tools 102-114 and/or the wafer/die transport tool 116 may be used to perform one or more of the semiconductor processing operations described in connection with FIGS. 3A-3N. In some implementations, one or more of the semiconductor processing operations described in connection with FIGS. 3A-3N may be performed using another semiconductor processing tool. While the semiconductor processing operations are illustrated as being performed in connection with the first semiconductor die 206, the semiconductor processing operations illustrated and described in connection with FIGS. 3A-3N may be performed to form the second semiconductor die 208 in a similar manner.

Turning to FIG. 3A, the substrate 224 may be provided. The substrate 224 may be provided in the form of a semiconductor wafer (e.g., the first semiconductor wafer 202) such as a silicon (Si) wafer. The first semiconductor die 206 may be formed on the substrate 224 along with a plurality of other first semiconductor dies 206.

As shown in FIG. 3B, the semiconductor devices 226 may be formed in and/or on the substrate 224 in the device layer 212 of the first semiconductor die 206. One or more of the semiconductor processing tools 102-114 may be used to form one or more portions of the semiconductor devices 226. For example, a deposition tool 102 may be used to perform various deposition operations to deposit layers of the semiconductor devices 226, and/or to deposit photoresist layers for etching the substrate 224 and/or portions of the deposited layers. As another example, an exposure tool 104 may be used to expose the photoresist layers to form patterns in the photoresist layers. As another example, a developer tool 106 may develop the patterns in the photoresist layers. As another example, an etch tool 108 may be used to etch the substrate 224 and/or portions of the deposited layers to form the semiconductor devices 226. As another example, a planarization tool 110 may be used to planarize portions of the semiconductor devices 226. As another example, a plating tool 112 may be used to deposit metal structures and/or layers of the semiconductor devices 226.

As shown in FIG. 3C, a deposition tool 102 is used to deposit the dielectric layer 228 over and/or on the substrate 224 and over and/or on the semiconductor devices 226. A deposition tool 102 is also used to deposit alternating layers of ESLs 232 and ILD layers 230 of the interconnect structure 216 of the first semiconductor die 206. A deposition tool 102, an exposure tool 104, a developer tool 106, an etch tool 108, a planarization tool 110, and/or a plating tool 112 are used to perform various operations to form the metallization layers 234 in the interconnect structure 216 of the first semiconductor die 206. The metallization layers 234 may be included in the ILD layers 230 and/or the ESLs 232, and may be electrically coupled with the semiconductor devices 226 in the device layer 212.

As shown in FIG. 3D, the nitride layer 236 of the bonding region 220 is formed over and/or on the interconnect structure 216 of the first semiconductor die 206. A deposition tool 102 may be used to deposit the nitride layer 236 using a PVD technique, an ALD technique, a CVD technique, an oxidation technique, another type of deposition technique described in connection with FIG. 1, and/or another suitable deposition technique. In some implementations, the planarization tool 110 may be used to planarize the nitride layer 236 after the nitride layer 236 is deposited.

As further shown in FIG. 3D, the ELK dielectric layer 238 of the bonding region 220 is formed over and/or on the nitride layer 236. A deposition tool 102 may be used to deposit the ELK dielectric layer 238 using a PVD technique, an ALD technique, a CVD technique, an oxidation technique, another type of deposition technique described in connection with FIG. 1, and/or another suitable deposition technique. In some implementations, the planarization tool 110 may be used to planarize the ELK dielectric layer 238 after the ELK dielectric layer 238 is deposited.

As shown in FIGS. 3E and 3F, recesses 302 are formed in and/or through the ELK dielectric layer 238 and the nitride layer 236. The top surfaces of the topmost metallization layers 234 in the interconnect structure 216 are exposed through the recesses 302. In some implementations, a dual damascene process is used to form the recesses 302. For example, and as shown in FIG. 3E, a via portion of the recesses 302 may be formed in and/or through the ELK dielectric layer 238 and the nitride layer 236. In particular, the via portion may be formed from a top surface of the ELK dielectric layer 238 through the ELK dielectric layer 238, and through the nitride layer 236. A deposition tool 102 may be used to form a photoresist layer on the ELK dielectric layer 238. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the ELK dielectric layer 238 and the nitride layer 236 to form the via portion of the recesses 302. In some implementations, a photoresist removal tool removes the remaining portions of the photoresist layer (e.g., using a chemical stripper and/or another technique).

A trench portion of the recesses 302 may be formed in the ELK dielectric layer 238 above the via portion. In particular, the trench portion may be formed from the top surface of the ELK dielectric layer 238 and into a portion of the ELK dielectric layer 238. A deposition tool 102 may be used to form a photoresist layer on the ELK dielectric layer 238. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the ELK dielectric layer 238 to form the trench portion of the recesses 302 in the ELK dielectric layer 238. In some implementations, a photoresist removal tool removes the remaining portions of the photoresist layer (e.g., using a chemical stripper and/or another technique).

FIGS. 3E and 3F illustrate an example via-first dual damascene procedure in which the recesses 302 are formed by forming the via portion before forming the trench portion. In some implementations, a trench-first dual damascene procedure in which the recesses 302 are formed by forming the trench portion before forming the via portion.

As shown in FIG. 3G, the metal interconnects 240 are formed in the via portion of the recesses 302 such that the metal interconnects 240 land on (and are electrically coupled and/or physically coupled with) the topmost metallization layer 234. The metal layers 242 are formed in the trench portion of the recesses 302 on the metal interconnects 240. The metal interconnects 240 and the metal layers 242 include one or more liner layers 304 and a conductive structure 306. The one or more liner layers 304 may include adhesion layers, barrier layers, and/or another type of liners that are conformally deposited on the sidewalls and/or the bottom surfaces of the recesses 302. Examples of materials for the one or more liner layers 304 include tantalum nitride (TaN), titanium nitride (TiN), ruthenium (Ru), cobalt (Co), and/or ruthenium oxide (RuOₓ), among other examples.

A deposition tool 102 may be used to deposit the one or more liner layers 304 using a PVD technique, an ALD technique, a CVD technique, another type of deposition technique described in connection with FIG. 1, and/or another suitable deposition technique. A deposition tool 102 and/or a plating tool 112 may be used to deposit the metal interconnects 240 and the metal layers 242 using a CVD technique, a PVD technique, an ALD technique, an electroplating technique, another deposition technique described above in connection with FIG. 1, and/or another suitable deposition technique. In some implementations, a seed layer is first deposited, and a metal interconnect 240 and/or a metal layer 242 are deposited on the seed layer. In some implementations, the planarization tool 110 is used to planarize the metal layers 242 after the metal layers 242 are deposited.

As shown in FIG. 3H, the carbide layer 244 is formed over and/or on the ELK dielectric layer 238. The carbide layer 244 also covers the metal layers 242. A deposition tool 102 may be used to deposit the carbide layer 244 using a PVD technique, an ALD technique, a CVD technique, another type of deposition technique described in connection with FIG. 1, and/or another suitable deposition technique. In some implementations, a planarization tool 110 is used to planarize the carbide layer 244 after the carbide layer 244 is deposited.

FIGS. 3I and 3J illustrate examples of forming the carbide layer 244. FIG. 3I illustrates an example of forming a single-layer structure for the carbide layer 244. FIG. 3J illustrates an example of forming a multiple-layer structure for the carbide layer 244. As shown in the example in FIG. 3I, the single-layer structure is deposited over and/or on the ELK dielectric layer 238.

As shown in the example in FIG. 3J, the first sub-layer 244a is deposited over and/or on the ELK dielectric layer 238, the second sub-layer 244b is deposited over and/or on the first sub-layer 244a, and the third sub-layer 244c is deposited over and/or on the second sub-layer 244b. Each of the sub-layers 244a-244c may be deposited in a respective CVD operation. The flow rate of a carbon precursor gas may be adjusted for each CVD operation to achieve a particular carbon concentration for the sub-layers 244a-244c. For example, the flow rate of the carbon precursor gas may be adjusted for a first CVD operation to achieve a first carbon concentration in the first sub-layer 244a, the flow rate of the carbon precursor gas may be adjusted for a second CVD operation to achieve a second carbon concentration in the second sub-layer 244b, and the flow rate of the carbon precursor gas may be adjusted for a third CVD operation to achieve a third carbon concentration in the third sub-layer 244c. The flow rate of the carbon precursor gas may be adjusted to be greater in the second CVD operation than in the first CVD operation such that the second carbon concentration in the second sub-layer 244b is greater than the first carbon concentration in the first sub-layer 244a. The flow rate of the carbon precursor gas may be adjusted to be greater in the third CVD operation than in the second CVD operation such that the third carbon concentration in the third sub-layer 244c is greater than the second carbon concentration in the second sub-layer 244b.

As shown in FIG. 3K, the dielectric layer 246 of the bonding region 220 is formed over and/or on the carbide layer 244. A deposition tool 102 may be used to deposit the dielectric layer 246 using a PVD technique, an ALD technique, a CVD technique, an oxidation technique, another type of deposition technique described in connection with FIG. 1, and/or another suitable deposition technique. In some implementations, the planarization tool 110 may be used to planarize the dielectric layer 246 after the dielectric layer 246 is deposited.

The nitride layer 250 of the bonding region 220 is formed over and/or on the dielectric layer 246. A deposition tool 102 may be used to deposit the nitride layer 250 using a PVD technique, an ALD technique, a CVD technique, another type of deposition technique described in connection with FIG. 1, and/or another suitable deposition technique. In some implementations, the planarization tool 110 may be used to planarize the nitride layer 250 after the nitride layer 250 is deposited.

The dielectric layer 252 is deposited over and/or on the nitride layer 250. A deposition tool 102 may be used to deposit the dielectric layer 252 using a PVD technique, an ALD technique, a CVD technique, an oxidation technique, another type of deposition technique described in connection with FIG. 1, and/or another suitable deposition technique. In some implementations, the planarization tool 110 may be used to planarize the dielectric layer 252 after the dielectric layer 252 is deposited.

The bonding dielectric layer 254 is deposited over and/or on the dielectric layer 252. A deposition tool 102 may be used to deposit the bonding dielectric layer 254 using a PVD technique, an ALD technique, a CVD technique, an oxidation technique, another type of deposition technique described in connection with FIG. 1, and/or another suitable deposition technique. In some implementations, the planarization tool 110 may be used to planarize the bonding dielectric layer 254 after the bonding dielectric layer 254 is deposited.

As shown in FIGS. 3L and 3M, recesses 308 are formed in and/or through the bonding dielectric layer 254, the dielectric layer 252, the nitride layer 250, the dielectric layer 246, and the carbide layer 244. The top surfaces of the metal layers 242 are exposed through the recesses 308. In some implementations, a dual damascene process is used to form the recesses 308. For example, and as shown in FIG. 3L, a via portion of the recesses 308 may be formed from a top surface of the bonding dielectric layer 254 through the bonding dielectric layer 254, the dielectric layer 252, the nitride layer 250, the dielectric layer 246, and the carbide layer 244. A deposition tool 102 may be used to form a photoresist layer on the bonding dielectric layer 254. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the bonding dielectric layer 254, the dielectric layer 252, the nitride layer 250, the dielectric layer 246, and the carbide layer 244 to form the via portion of the recesses 308. In some implementations, a photoresist removal tool removes the remaining portions of the photoresist layer (e.g., using a chemical stripper and/or another technique).

A trench portion of the recesses 308 may be formed in the ELK dielectric layer 238 above the via portion. In particular, the trench portion may be formed from the top surface of the bonding dielectric layer 254 and through the bonding dielectric layer 254, the dielectric layer 252, and the nitride layer 250. A deposition tool 102 may be used to form a photoresist layer on the bonding dielectric layer 254. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the bonding dielectric layer 254, the dielectric layer 252, and the nitride layer 250 to form the trench portion of the recesses 308 in the bonding dielectric layer 254, the dielectric layer 252, and the nitride layer 250. In some implementations, a photoresist removal tool removes the remaining portions of the photoresist layer (e.g., using a chemical stripper and/or another technique).

FIGS. 3L and 3M illustrate an example via-first dual damascene procedure in which the recesses 308 are formed by forming the via portion before forming the trench portion. In some implementations, a trench-first dual damascene procedure in which the recesses 308 are formed by forming the trench portion before forming the via portion.

As shown in FIG. 3N, the bonding vias 248 are formed in the via portion of the recesses 308 such that the bonding vias 248 land on (and are electrically coupled and/or physically coupled with) the metal layers 242. The bonding pads 256 are formed in the trench portion of the recesses 308 on the bonding vias 248. The bonding vias 248 and the bonding pads 256 include one or more liner layers 310 and a conductive structure 312. The one or more liner layers 310 may include adhesion layers, barrier layers, and/or another type of liners that are conformally deposited on the sidewalls and/or the bottom surfaces of the recesses 308. Examples of materials for the one or more liner layers 310 include tantalum nitride (TaN), titanium nitride (TiN), ruthenium (Ru), cobalt (Co), and/or ruthenium oxide (RuOₓ), among other examples.

A deposition tool 102 may be used to deposit the one or more liner layers 310 using a PVD technique, an ALD technique, a CVD technique, another type of deposition technique described in connection with FIG. 1, and/or another suitable deposition technique. A deposition tool 102 and/or a plating tool 112 may be used to deposit the bonding vias 248 and the bonding pads 256 using a CVD technique, a PVD technique, an ALD technique, an electroplating technique, another deposition technique described above in connection with FIG. 1, and/or another suitable deposition technique. In some implementations, a seed layer is first deposited, and a bonding via 248 and/or a bonding pad 256 are deposited on the seed layer. In some implementations, the planarization tool 110 is used to planarize the bonding pads 256 after the bonding pads 256 are deposited.

In some implementations, an annealing operation may be performed to reflow the conductive structures 312 of the bonding vias 248 and/or of the bonding pads 256 to remove voids in the bonding vias 248 and/or of the bonding pads 256. The carbon-containing dielectric material of the carbide layer 244 is harder than other dielectric materials such as silicon nitride (SiₓN_{y}) and silicon oxide (SiOₓ), which provides a closer match of thermal expansion and contraction coefficients between the carbide layer 244 and the bonding vias 248 than other dielectric materials. This reduces the magnitude of and/or the likelihood of stress migration between the bonding vias 248 and the carbide layer 244, which reduces the likelihood of discontinuity formation (e.g., voids, cracks, delamination, peeling) in the bonding vias 248.

As indicated above, FIGS. 3A-3N are provided as an example. Other examples may differ from what is described with regard to FIGS. 3A-3N. Moreover, as indicated above, the semiconductor processing operations described in connection with FIGS. 3A-3N may be performed to form the second semiconductor die 208 in a similar manner.

FIGS. 4A and 4B are diagrams of an example implementation 400 of forming a semiconductor device 200 described herein. In particular, the example implementation 400 includes an example of bonding the first semiconductor die 206 and the second semiconductor die 208 to form the semiconductor device 200. In some implementations, one or more of the semiconductor processing tools 102-114 and/or the wafer/die transport tool 116 may be used to perform one or more of the semiconductor processing operations described in connection with FIGS. 4A and 4B. In some implementations, one or more of the semiconductor processing operations described in connection with FIGS. 4A and 4B may be performed using another semiconductor processing tool.

As shown in 4A and 4B, a bonding operation is performed to bond the first semiconductor die 206 and the second semiconductor die 208 at the bonding interface 210 such that the first semiconductor die 206 and the second semiconductor die 208 are vertically arranged or stacked. The first semiconductor die 206 and the second semiconductor die 208 may be vertically arranged or stacked in a wafer on wafer (WoW) configuration, a die on wafer configuration, a die on die configuration, and/or another direct bonding configuration. The bonding tool 114 may perform a bonding operation to bond the first semiconductor die 206 and the second semiconductor die 208 at the bonding interface 210. The bonding operation may include forming a direct bond between the first semiconductor die 206 and the second semiconductor die 208 through the physical connection of the bonding pads 256 and 290, and the physical connection of the bonding dielectric layers 254 and 288. At the bonding interface 210, a direct metal-to-metal bond is formed between the bonding pads 256 and 290, and a direct dielectric-to-dielectric bond is formed between the bonding dielectric layers 254 and 288. Accordingly, the bonding operation may be referred to as a hybrid bonding operation.

In some implementations, the first semiconductor die 206 and the second semiconductor die 208 are bonded as part of bonding the first semiconductor wafer 202 and the second semiconductor wafer 204 in the bonding operation. Accordingly, the semiconductor device 200 (and other semiconductor devices 200) may be diced or cut from the bonded first semiconductor wafer 202 and the second semiconductor wafer 204 and packaged.

As indicated above, FIGS. 4A and 4B are provided as an example. Other examples may differ from what is described with regard to FIGS. 4A and 4B.

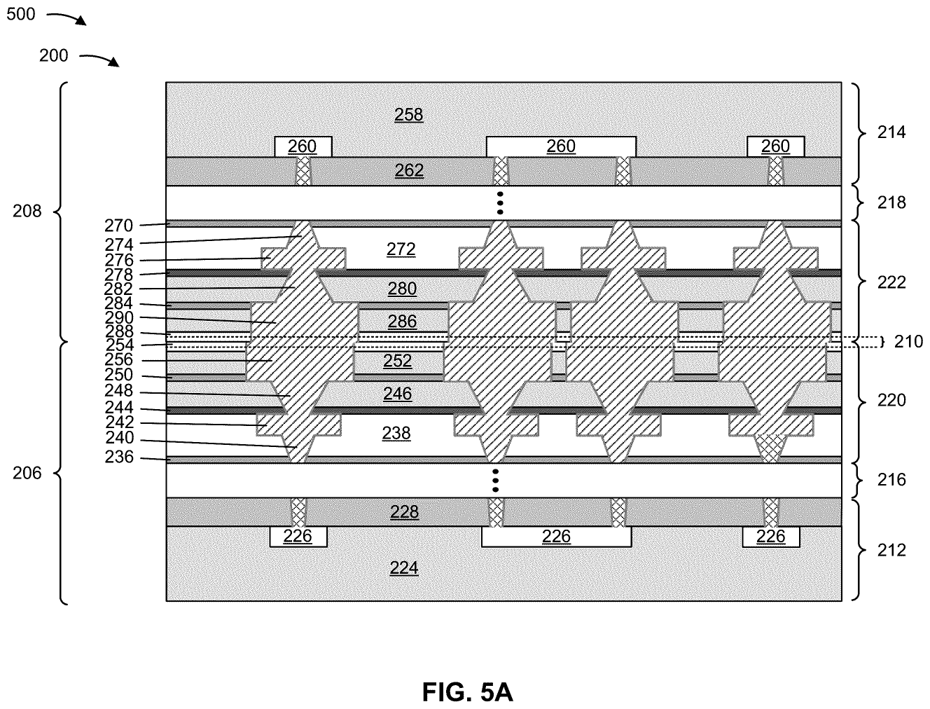

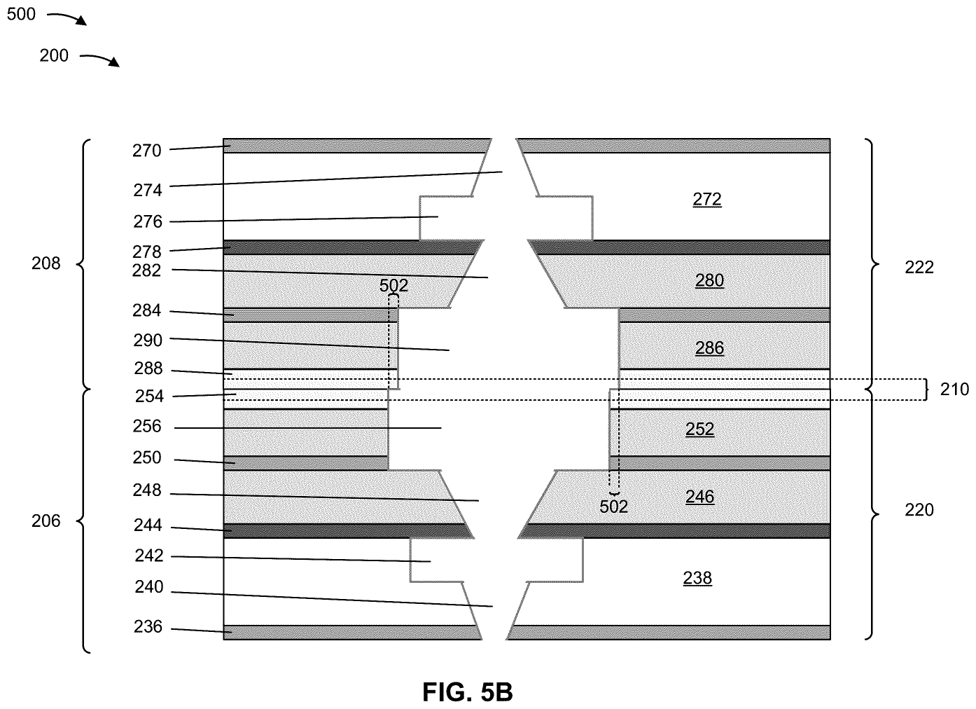

FIGS. 5A and 5B are diagrams of an example implementation 500 of the semiconductor device 200 described herein. As shown in FIGS. 5A and 5B, the first semiconductor die 206 and the second semiconductor die 208 are offset from each other at the bonding interface 210 in the example implementation 500. A small amount of misalignment may occur at the bonding pads 256 and 290, resulting an offset 502 at the sides of the bonding pads 256 and 290. However, minor misalignment of the bonding pads 256 and 290 may be accommodated in the semiconductor device 200, and the ELK dielectric layers 238 and 272 and the carbide layers 244 and 278 still resist thermal stress migration and promote low RC delays in the semiconductor device 200.

As indicated above, FIGS. 5A and 5B are provided as an example. Other examples may differ from what is described with regard to FIGS. 5A and 5B.

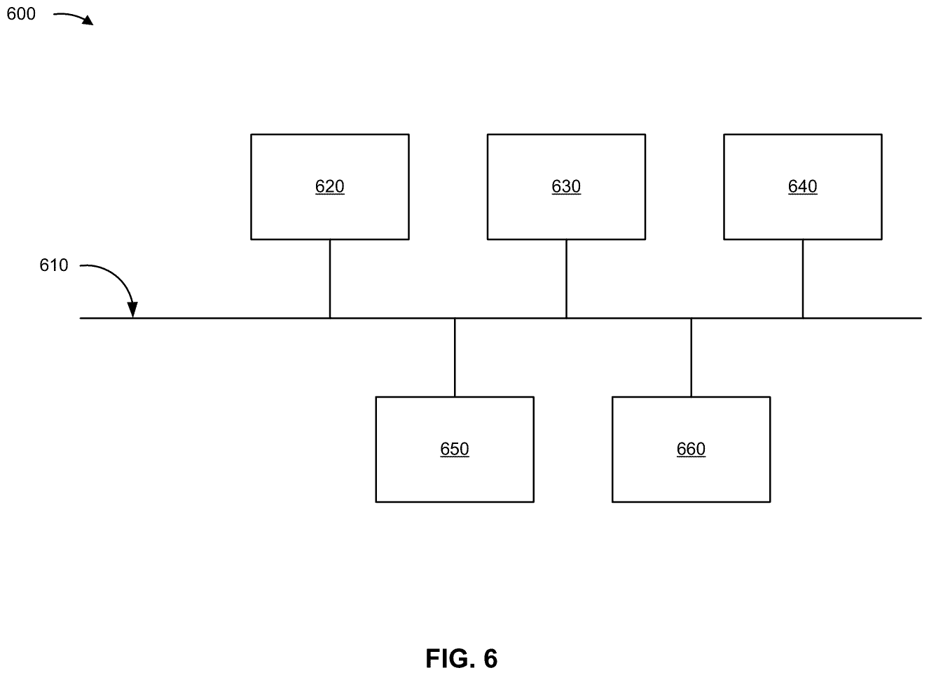

FIG. 6 is a diagram of example components of a device 600 described herein. In some implementations, one or more of the semiconductor processing tools 102-114 and/or the wafer/die transport tool 116 may include one or more devices 600 and/or one or more components of the device 600. As shown in FIG. 6, the device 600 may include a bus 610, a processor 620, a memory 630, an input component 640, an output component 650, and/or a communication component 660.

The bus 610 may include one or more components that enable wired and/or wireless communication among the components of the device 600. The bus 610 may couple together two or more components of FIG. 6, such as via operative coupling, communicative coupling, electronic coupling, and/or electric coupling. For example, the bus 610 may include an electrical connection (e.g., a wire, a trace, and/or a lead) and/or a wireless bus. The processor 620 may include a central processing unit, a graphics processing unit, a microprocessor, a controller, a microcontroller, a digital signal processor, a field-programmable gate array, an application-specific integrated circuit, and/or another type of processing component. The processor 620 may be implemented in hardware, firmware, or a combination of hardware and software. In some implementations, the processor 620 may include one or more processors capable of being programmed to perform one or more operations or processes described elsewhere herein.

The memory 630 may include volatile and/or nonvolatile memory. For example, the memory 630 may include random access memory (RAM), read only memory (ROM), a hard disk drive, and/or another type of memory (e.g., a flash memory, a magnetic memory, and/or an optical memory). The memory 630 may include internal memory (e.g., RAM, ROM, or a hard disk drive) and/or removable memory (e.g., removable via a universal serial bus connection). The memory 630 may be a non-transitory computer-readable medium. The memory 630 may store information, one or more instructions, and/or software (e.g., one or more software applications) related to the operation of the device 600. In some implementations, the memory 630 may include one or more memories that are coupled (e.g., communicatively coupled) to one or more processors (e.g., processor 620), such as via the bus 610. Communicative coupling between a processor 620 and a memory 630 may enable the processor 620 to read and/or process information stored in the memory 630 and/or to store information in the memory 630.

The input component 640 may enable the device 600 to receive input, such as user input and/or sensed input. For example, the input component 640 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 650 may enable the device 600 to provide output, such as via a display, a speaker, and/or a light-emitting diode. The communication component 660 may enable the device 600 to communicate with other devices via a wired connection and/or a wireless connection. For example, the communication component 660 may include a receiver, a transmitter, a transceiver, a modem, a network interface card, and/or an antenna.

The device 600 may perform one or more operations or processes described herein. For example, a non-transitory computer-readable medium (e.g., memory 630) may store a set of instructions (e.g., one or more instructions or code) for execution by the processor 620. The processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry may be used instead of or in combination with the instructions to perform one or more operations or processes described herein. Additionally, or alternatively, the processor 620 may be configured to perform one or more operations or processes described herein. Thus, implementations described herein are not limited to any specific combination of hardware circuitry and software.

The number and arrangement of components shown in FIG. 6 are provided as an example. The device 600 may include additional components, fewer components, different components, or differently arranged components than those shown in FIG. 6. Additionally, or alternatively, a set of components (e.g., one or more components) of the device 600 may perform one or more functions described as being performed by another set of components of the device 600.

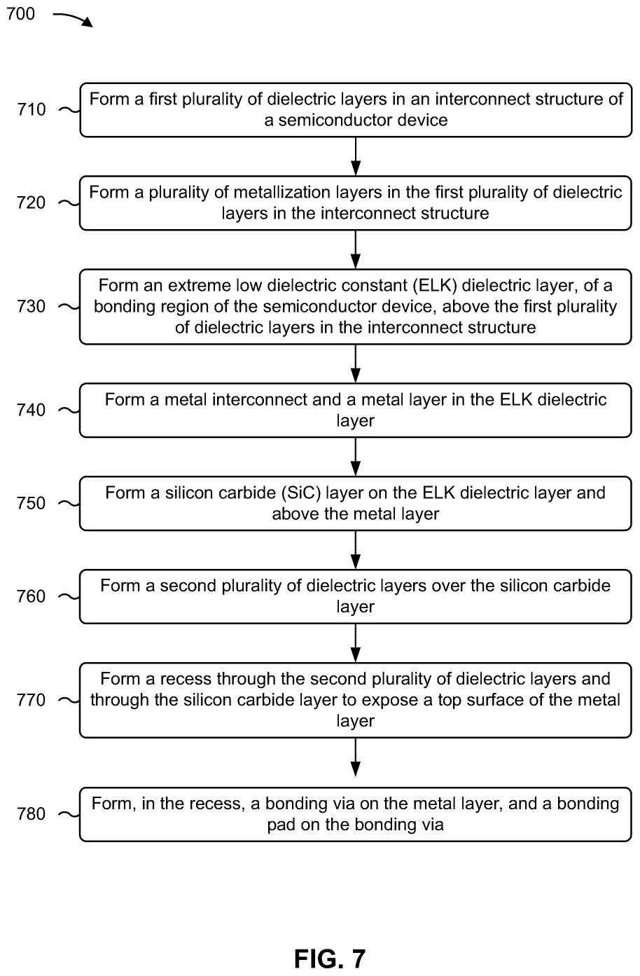

FIG. 7 is a flowchart of an example process 700 associated with forming a semiconductor device described herein. In some implementations, one or more process blocks of FIG. 7 are performed using one or more semiconductor processing tools (e.g., one or more of the semiconductor processing tools 102-114). Additionally, or alternatively, one or more process blocks of FIG. 7 may be performed using one or more components of device 600, such as processor 620, memory 630, input component 640, output component 650, and/or communication component 660.

As shown in FIG. 7, process 700 may include forming a first plurality of dielectric layers in an interconnect structure of a semiconductor device (block 710). For example, one or more of the semiconductor processing tools 102-114 may be used to form a first plurality of dielectric layers (e.g., the ILD layers 230, the ESLs 232, the ILD layers 264, the ESLs 266) in an interconnect structure (e.g., the interconnect structure 216, the interconnect structure 218) of a semiconductor device 200, as described herein.

As further shown in FIG. 7, process 700 may include forming a plurality of metallization layers in the first plurality of dielectric layers in the interconnect structure (block 720). For example, one or more of the semiconductor processing tools 102-114 may be used to form a plurality of metallization layers (e.g., the metallization layers 234, the metallization layers 268) in the first plurality of dielectric layers in the interconnect structure, as described herein.

As further shown in FIG. 7, process 700 may include forming an ELK dielectric layer, of a bonding region of the semiconductor device, above the first plurality of dielectric layers in the interconnect structure (block 730). For example, one or more of the semiconductor processing tools 102-114 may be used to form an ELK dielectric layer (e.g., the ELK dielectric layer 238, the ELK dielectric layer 272), of a bonding region (e.g., the bonding region 220, the bonding region 222) of the semiconductor device 200, above the first plurality of dielectric layers in the interconnect structure, as described herein.

As further shown in FIG. 7, process 700 may include forming a metal interconnect and a metal layer in the ELK dielectric layer (block 740). For example, one or more of the semiconductor processing tools 102-114 may be used to form a metal interconnect (e.g., a metal interconnect 240, a metal interconnect 274) and a metal layer (e.g., a metal layer 242, a metal layer 276) in the ELK dielectric layer, as described herein.

As further shown in FIG. 7, process 700 may include forming a silicon carbide (SIC) layer on the ELK dielectric layer and above the metal layer (block 750). For example, one or more of the semiconductor processing tools 102-114 may be used to form a silicon carbide (SIC) layer (e.g., a carbide layer 244, a carbide layer 278) on the ELK dielectric layer and above the metal layer, as described herein.

As further shown in FIG. 7, process 700 may include forming a second plurality of dielectric layers over the silicon carbide layer (block 760). For example, one or more of the semiconductor processing tools 102-114 may be used to form a second plurality of dielectric layers (e.g., the dielectric layer 246, the nitride layer 250, the dielectric layer 252, the bonding dielectric layer 254, the dielectric layer 280, the nitride layer 284, the dielectric layer 286, the bonding dielectric layer 288) over the silicon carbide layer, as described herein.

As further shown in FIG. 7, process 700 may include forming a recess through the second plurality of dielectric layers and through the silicon carbide layer to expose a top surface of the metal layer (block 770). For example, one or more of the semiconductor processing tools 102-114 may be used to form a recess 308 through the second plurality of dielectric layers and through the silicon carbide layer to expose a top surface of the metal layer, as described herein.

As further shown in FIG. 7, process 700 may include forming, in the recess, a bonding via on metal layer and a bonding pad on the bonding via (block 780). For example, one or more of the semiconductor processing tools 102-114 may be used to form, in the recess, a bonding via (e.g., a bonding via 248, a bonding via 282) on metal layer and a bonding pad (e.g., a bonding pad 256, a bonding pad 290) on the bonding via, as described herein.

Process 700 may include additional implementations, such as any single implementation or any combination of implementations described below and/or in connection with one or more other processes described elsewhere herein.

In a first implementation, forming the silicon carbide layer includes forming a single-layer silicon carbide layer in a chemical vapor deposition operation.

In a second implementation, alone or in combination with the first implementation, forming the silicon carbide layer includes forming a first sub-layer (e.g., a first sub-layer 244a, a first sub-layer 278a), of the silicon carbide layer, having a first carbon concentration; forming a second sub-layer (e.g., a second sub-layer 244b, a second sub-layer 278b) of the silicon carbide layer, on the first sub-layer, having a second carbon concentration that is greater than the first carbon concentration; and forming a third sub-layer (e.g., a third sub-layer 244c, a third sub-layer 278c) of the silicon carbide layer, on the second sub-layer, having a third carbon concentration that is greater than the second carbon concentration.

In a third implementation, alone or in combination with one or more of the first and second implementations, forming the first sub-layer, the second sub-layer, and the third sub-layer includes adjusting a flow rate of a carbon precursor gas to achieve the first carbon concentration in the first sub-layer, the second carbon concentration in the second sub-layer, and the third carbon concentration in the third sub-layer.

In a fourth implementation, alone or in combination with one or more of the first through third implementations, forming the metal interconnect and the metal layer in the ELK dielectric layer includes forming another recess 302 in the ELK dielectric layer, forming a liner layer 304 of the metal interconnect and of the metal layer on the ELK dielectric layer in the recess, and filling the recess 302 with a conductive structure 306 over the liner layer 304.

In a fifth implementation, alone or in combination with one or more of the first through fourth implementations, forming the bonding via includes forming a liner layer 310 on sidewalls of the recess 308 corresponding to the silicon carbide layer, and forming a conductive structure 312 over the liner layer 310.

In a sixth implementation, alone or in combination with one or more of the first through fifth implementations, the silicon carbide layer includes a combination of silicon (Si), carbon (C), nitrogen (N), hydrogen (H), and oxygen (O).

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, a metal layer of a semiconductor device may be included in an extreme low dielectric constant (ELK) dielectric layer in an interconnect structure of the semiconductor device. The metal layer may be coupled with a bonding via that extends through a silicon carbide (SiC) layer in a bonding region of the semiconductor device. The ELK dielectric layer and/or the silicon carbide layer reduces stress migration in the semiconductor relative to the use of other dielectric materials such as silicon nitride and/or silicon glass. The ELK dielectric layer and/or the silicon carbide layer also reduces resistance-capacitance (RC) delay in the interconnect structure relative to the use of other dielectric materials. The ELK dielectric layer and/or the silicon carbide layer provides improved adhesion with the metal material(s) (e.g., copper and/or another metal material) of the metal layer and/or of the bonding via coupled with the metal layer. This may reduce the likelihood of stress migration in the semiconductor device, thereby reducing the likelihood of void formation in the semiconductor device. The reduced likelihood of void formation may reduce electrical resistance in the interconnect structure and/or in the bonding region, which may improve the performance of the semiconductor device and/or may increase semiconductor processing yield of semiconductor devices formed on a semiconductor wafer, among other examples.

As described in greater detail above, some implementations described herein provide a semiconductor device. The semiconductor device includes a device layer. The semiconductor device includes an interconnect structure, above the device layer, that includes a plurality of dielectric layers and a plurality of metallization layers included in the plurality of dielectric layers. The semiconductor device includes a bonding region, above the interconnect structure, that includes a metal layer above the plurality of metallization layers, a silicon carbide (SIC) layer above the plurality of dielectric layers and above the metal layer, a bonding via above and coupled with the metal layer, and a bonding pad above and coupled with the bonding via, where the bonding via extends through the silicon carbide layer.

As described in greater detail above, some implementations described herein provide a semiconductor device. The semiconductor device includes a first semiconductor die that includes a first device layer and a first interconnect structure above the first device layer. The first interconnect structure includes a first plurality of dielectric layers and a first plurality of metallization layers included in the first plurality of dielectric layers. The first semiconductor die includes a first bonding region, above the first interconnect structure, that includes a first ELK dielectric layer above the first plurality of dielectric layers, a first metal layer above the first plurality of metallization layers and included in the first ELK dielectric layer, a first bonding via above and coupled with the first metal layer, where the first bonding via is above the first ELK dielectric layer, and a first bonding pad above and coupled with the first bonding via. The semiconductor device includes a second semiconductor die that includes a second device layer, a second interconnect structure below the second device layer, and a second bonding region below the second interconnect structure. The second interconnect structure includes a second plurality of dielectric layers and a second plurality of metallization layers included in the first plurality of dielectric layers. The second bonding region includes a second ELK dielectric layer below the second plurality of dielectric layers, a second metal layer below the second plurality of metallization layers and included in the second ELK dielectric layer, a second bonding via below and coupled with the first metal layer, where the second bonding via is below the second ELK dielectric layer, and a second bonding pad below and coupled with the second bonding via, where the first semiconductor die and the second semiconductor die are bonded at the first bonding pad and the second bonding pad.

As described in greater detail above, some implementations described herein provide a method. The method includes forming a first plurality of dielectric layers in an interconnect structure of a semiconductor device. The method includes forming a plurality of metallization layers in the first plurality of dielectric layers in the interconnect structure. The method includes forming an ELK dielectric layer, of a bonding region of the semiconductor device, above the first plurality of dielectric layers in the interconnect structure. The method includes forming a metal interconnect and a metal layer in the ELK dielectric layer. The method includes forming a silicon carbide (SiC) layer on the ELK dielectric layer and above the metal layer. The method includes forming a second plurality of dielectric layers over the silicon carbide layer. The method includes forming a recess through the second plurality of dielectric layers and through the silicon carbide layer to expose a top surface of the metal layer. The method includes forming, in the recess, a bonding via on metal layer a bonding pad on the bonding via.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device layer;
an interconnect structure, above the device layer, comprising:
a plurality of dielectric layers; and
a plurality of metallization layers included in the plurality of dielectric layers; and
a bonding region, above the interconnect structure, comprising:
a metal layer above the plurality of metallization layers;
a silicon carbide (SiC) layer above the plurality of dielectric layers and above the metal layer;
a bonding via structure above and coupled with the metal layer; and
a bonding pad structure above and coupled with the HBC structure,
wherein the bonding via extends through the silicon carbide layer.

2. The semiconductor device of claim 1, wherein the silicon carbide layer comprises a multiple-layer structure that includes:
a first sub-layer having a first carbon (C) concentration; and
a second sub-layer, on the first sub-layer, having a second carbon concentration that is greater than the first carbon concentration.

3. The semiconductor device of claim 2, wherein the multiple-layer structure includes a third sub-layer, on the second sub-layer, having a third carbon concentration that is greater than the second carbon concentration.

4. The semiconductor device of claim 1, wherein the silicon carbide layer comprises a combination of:
silicon (Si),
carbon (C), and
at least one of:
nitrogen (N),
hydrogen (H), or
oxygen (O).

5. The semiconductor device of claim 1, wherein the bonding region further comprises:
an extreme low dielectric constant (ELK) dielectric layer under the silicon carbide layer, wherein the metal layer is included in the ELK dielectric layer.

6. The semiconductor device of claim 5, wherein the ELK dielectric comprises at least one of:
carbon doped silicon oxide (C—SiOₓ),
bis-benzocyclobutenes (BCB),
polytetrafluoroethylene (PTFE), or
a silicon oxycarbide (SiOC) polymer.

7. A semiconductor device, comprising:
a first semiconductor die, comprising:
a first device layer;
a first interconnect structure, above the first device layer, comprising:
a first plurality of dielectric layers; and
a first plurality of metallization layers included in the first plurality of dielectric layers; and
a first bonding region, above the first interconnect structure, comprising:
a first extreme low dielectric constant (ELK) dielectric layer above the first plurality of dielectric layers;
a first metal layer above the first plurality of metallization layers and included in the first ELK dielectric layer;
a first bonding via above and coupled with the first metal layer,
wherein the first bonding via is above the first ELK dielectric layer; and
a first bonding pad above and coupled with the first bonding via;
a second semiconductor die, comprising:
a second device layer;
a second interconnect structure, below the second device layer, comprising:
a second plurality of dielectric layers; and
a second plurality of metallization layers included in the first plurality of dielectric layers; and
a second bonding region, below the second interconnect structure, comprising:
a second ELK dielectric layer below the second plurality of dielectric layers;
a second metal layer below the second plurality of metallization layers and included in the second ELK dielectric layer;
a second bonding via below and coupled with the second metal layer,
wherein the second bonding via is below the second ELK dielectric layer; and
a second bonding pad below and coupled with the second bonding via,
wherein the first semiconductor die and the second semiconductor die are bonded at the first bonding pad and the second bonding pad.

8. The semiconductor device of claim 7, wherein the first semiconductor die further comprises a first silicon carbide (SiC) layer above the first plurality of dielectric layers and above the first metal layer,
wherein the first bonding via extends through the first silicon carbide layer; and
wherein the second semiconductor die further comprises a second silicon carbide (SiC) layer below the second plurality of dielectric layers and below the second metal layer,
wherein the second bonding via extends through the second silicon carbide layer.

9. The semiconductor device of claim 8, wherein the first silicon carbide layer comprises a multiple-layer structure that includes:
a first sub-layer having a first carbon (C) concentration; and
a second sub-layer, on the first sub-layer, having a second carbon concentration that is greater than the first carbon concentration.

10. The semiconductor device of claim 9, wherein the multiple-layer structure includes a third sub-layer, on the second sub-layer, having a third carbon concentration that is greater than the second carbon concentration.

11. The semiconductor device of claim 9, wherein the second silicon carbide layer comprises a single-layer structure.

12. The semiconductor device of claim 9, wherein the second silicon carbide layer comprises another multiple-layer structure that includes:
a third sub-layer having a third carbon (C) concentration; and
a fourth sub-layer, under the third sub-layer, having a fourth carbon concentration that is greater than the third carbon concentration.

13. The semiconductor device of claim 12, wherein the multiple-layer structure includes a fifth sub-layer, on the second sub-layer, having a fifth carbon concentration that is greater than the second carbon concentration; and
wherein the other multiple-layer structure includes a sixth sub-layer, on the fourth sub-layer, having a sixth carbon concentration that is greater than the fourth carbon concentration.

14. A method, comprising:
forming a first plurality of dielectric layers in an interconnect structure of a semiconductor device;
forming a plurality of metallization layers in the first plurality of dielectric layers in the interconnect structure;
forming an extreme low dielectric constant (ELK) dielectric layer, of a bonding region of the semiconductor device, above the first plurality of dielectric layers in the interconnect structure;
forming a metal interconnect and a metal layer in the ELK dielectric layer;
forming a silicon carbide (SiC) layer on the ELK dielectric layer and above the metal layer;
forming a second plurality of dielectric layers over the silicon carbide layer;
forming a recess through the second plurality of dielectric layers and through the silicon carbide layer to expose a top surface of the metal layer; and
forming, in the recess:
a bonding via on the metal layer; and
a bonding pad on the bonding via.

15. The method of claim 14, wherein forming the silicon carbide layer comprises:
forming a single-layer silicon carbide layer in a chemical vapor deposition operation.

16. The method of claim 14, wherein forming the silicon carbide layer comprises:
forming a first sub-layer, of the silicon carbide layer, having a first carbon concentration;
forming a second sub-layer of the silicon carbide layer, on the first sub-layer, having a second carbon concentration that is greater than the first carbon concentration; and
forming a third sub-layer of the silicon carbide layer, on the second sub-layer, having a third carbon concentration that is greater than the second carbon concentration.

17. The method of claim 16, wherein forming the first sub-layer, the second sub-layer, and the third sub-layer comprises:
adjusting a flow rate of a carbon precursor gas to achieve the first carbon concentration in the first sub-layer, the second carbon concentration in the second sub-layer, and the third carbon concentration in the third sub-layer.

18. The method of claim 14, wherein forming the metal interconnect and the metal layer in the ELK dielectric layer comprises:
forming another recess in the ELK dielectric layer;
forming a liner layer of the metal interconnect and of the metal layer on the ELK dielectric layer in the recess; and
filling the recess with a conductive structure over the liner layer.

19. The method of claim 14, wherein forming the bonding via comprises:
forming a liner layer on sidewalls of the recess corresponding to the silicon carbide layer; and
forming a conductive structure over the liner layer.

20. The method of claim 14, wherein the silicon carbide layer comprises a combination of:
silicon (Si),
carbon (C),
nitrogen (N),
hydrogen (H), and
oxygen (O).
